(19) United States
(12) Patent Application Publication
(10) Pub. No.: US 2025/0309106 A1
(43) Pub. Date: Oct. 2, 2025

(54) INTEGRATED VOLTAGE REGULATOR, SEMICONDUCTOR DEVICE WITH INTEGRATED VOLTAGE REGULATOR, AND METHODS OF MANUFACTURING THE SAME

(71) Applicant: Taiwan Semiconductor Manufacturing Company, Ltd., Hsinchu (TW)

(72) Inventors: Chin I Wang, Tainan City (TW); Tzu-Yu Lin, Taoyuan City (TW)

(73) Assignee: Taiwan Semiconductor Manufacturing Company, Ltd., Hsinchu (TW)

(21) Appl. No.: 18/624,130

(22) Filed: Apr. 2, 2024

(51) Int. Cl. H01L 23/522; H01L 23/528; H01L 23/64

(52) U.S. Cl. CPC H01L 23/5227; H01L 23/5226; H01L 23/5283; H01L 23/645; H01L 2924/30107

(57) ABSTRACT

An integrated voltage regulator includes a lower portion, an upper portion, and a conductive feature. The lower portion includes at least one first anti-ferromagnetic layer and at least one first ferromagnetic layer stacked on the at least one first anti-ferromagnetic layer. The upper portion includes at least one second anti-ferromagnetic layer and at least one second ferromagnetic layer stacked on the at least one second anti-ferromagnetic layer. The conductive feature interposes between the lower portion and the upper portion.

### BACKGROUND

Developments in shrinking sizes of semiconductor devices and electronic components make the integration of more devices and components into a given volume possible and lead to high integration density of various semiconductor devices and/or electronic components. Integrated circuit applications currently have increasingly more functions built therein, and are thus formed to be increasingly larger. Accordingly, many types of semiconductor devices and/or electronic components have been developed to suit to customized requirements of integrated circuits. Power networks are also built inside the packages to provide power to the device dies.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 12 are schematic plane or cross-sectional views of various stages in manufacturing an integrated voltage regulator in accordance with some embodiments of the disclosure.

FIG. 13 through FIG. 18 are schematic, cross-sectional views respectively showing various embodiments of an integrated voltage regulator in accordance with the disclosure.

FIG. 19 to FIG. 20 are schematic plane or cross-sectional views of various stages in manufacturing a semiconductor device with an integrated voltage regulator in accordance with some embodiments of the disclosure.

FIG. 21 is a schematic cross-sectional view of a semiconductor package in accordance with some embodiments of the disclosure.

FIG. 22 through FIG. 28 are schematic, cross-sectional views respectively showing various embodiments of an integrated voltage regulator in accordance with the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, “fifth”, “sixth”, “seventh”, and the like, may be used herein for ease of description to describe similar or different element(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the disclosure provides applicable concepts that can be embodied in a wide variety of specific contexts. The embodiments are intended to provide further explanations but are not used to limit the scope of the disclosure. The specific embodiment(s) described herein is related to an integrated voltage inductor (IVR) having a conductive feature surrounding by an upper portion and a lower portion, where the upper portion and the lower portion are in a form of multi-layer structure, and the multi-layer structure includes a layer of ferromagnetic material and a layer of anti-ferromagnetic material. In some embodiments of the disclosure, at least one of the upper portion and the lower portion includes a stack of sub-layers, where the sub-layers each are in a form of the abovementioned multi-layer structure. Owing to the multi-layer structure of the upper portion and the lower portion, the operation frequency can be increased (e.g., boosted to be greater than 100 MGz), thereby improving the performance of a semiconductor device equipped with such IVR. In some embodiments of the disclosure, a sidewall of the upper portion indented from a sidewall of the lower portion. With such configuration, the inductance of the IVR is increased, and an overall occupied area of the IVR can be reduced, thereby further improving the performance of the semiconductor device equipped with such IVR. In addition, the semiconductor device is integrated with one or more IVRs, a shorten distance between an IVR and a respective electronic component(s) (e.g., a logic component, a memory component, a capacitor, a resistor, a diode, a photodiode, a fuse, other suitable electronic component, and the like) can be achieved, so that the power loss during the transmission and distribution of power (e.g., provided by an external power source) can be greatly reduced, thereby efficiently saving energy. The manufacture of such IVR is compatible to advanced manufacturing process. In some embodiments of the disclosure, the IVR may also be referred to as IVR inductor.

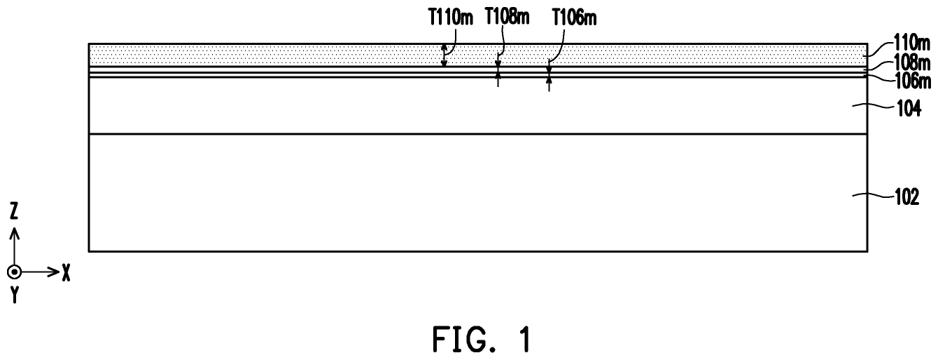

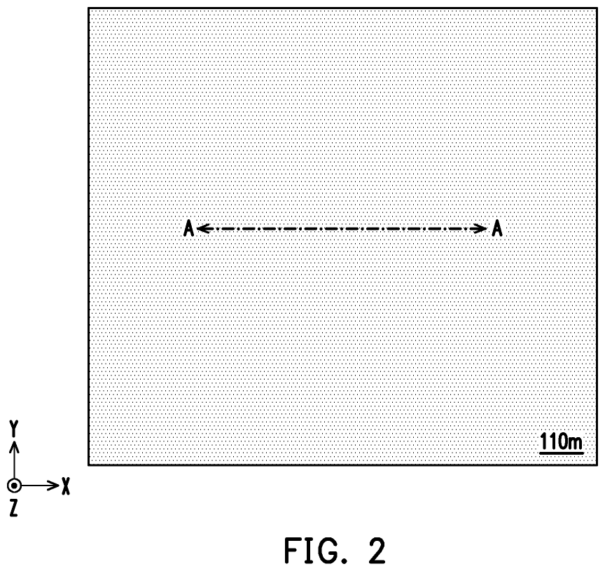

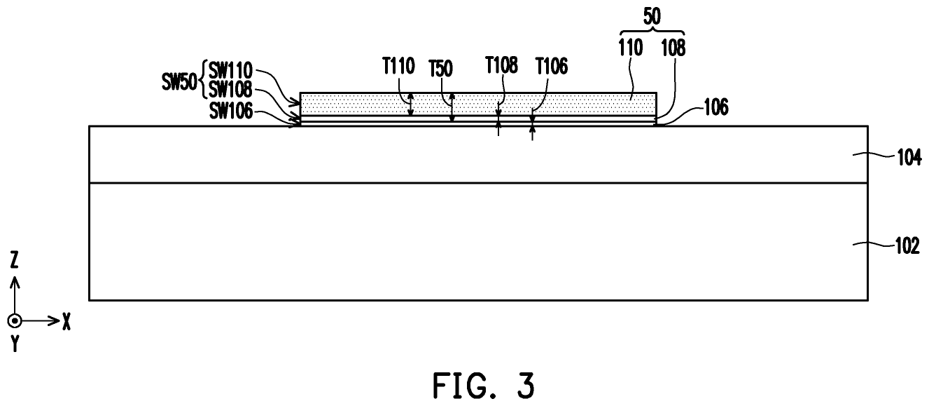

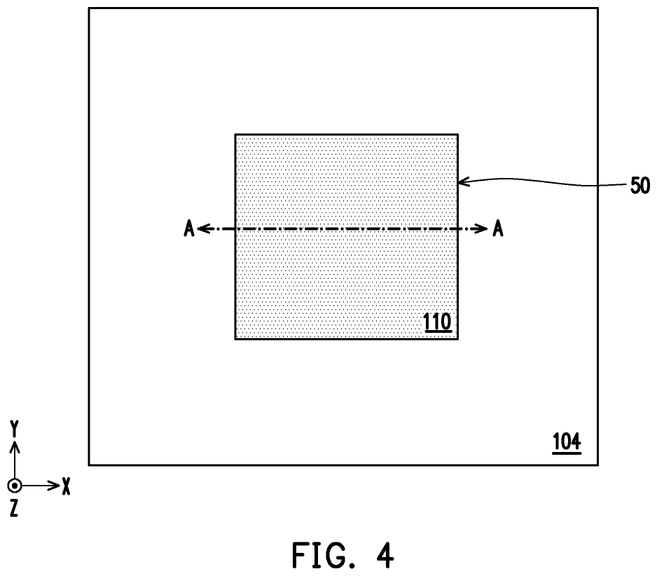

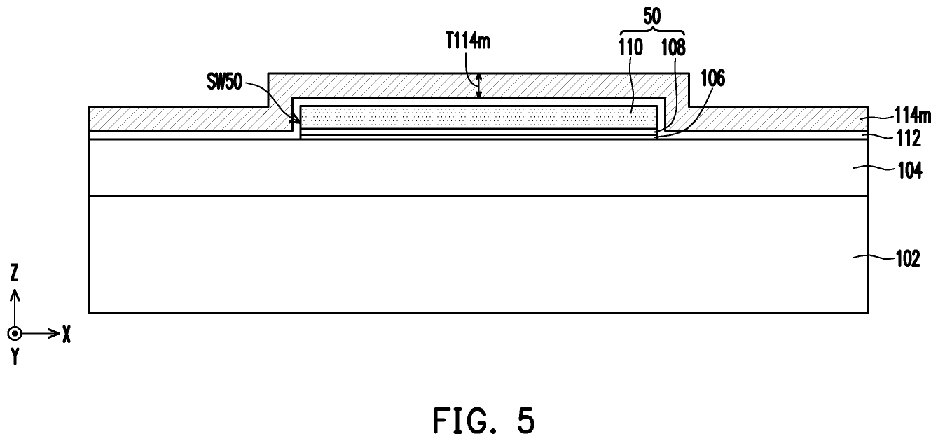

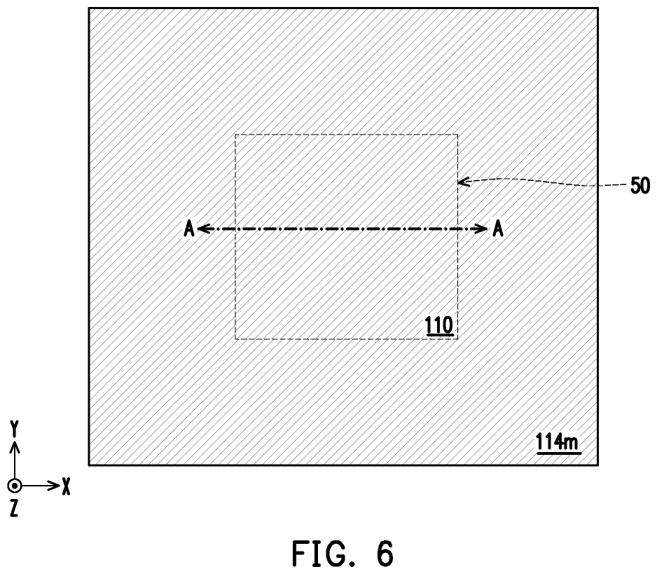

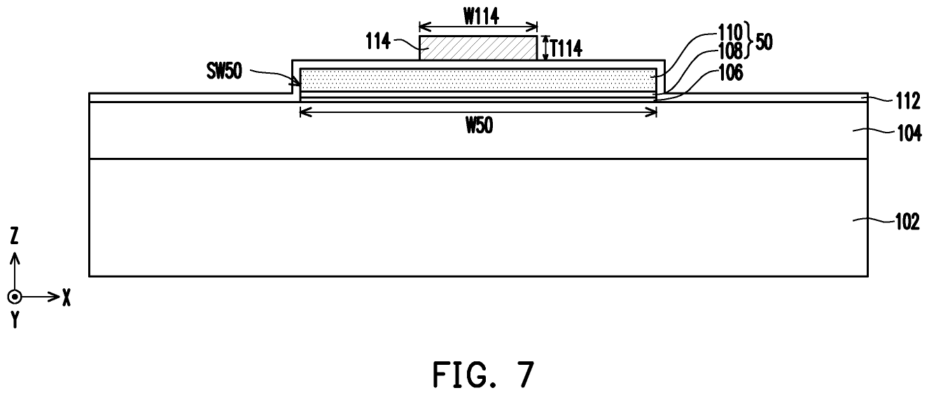

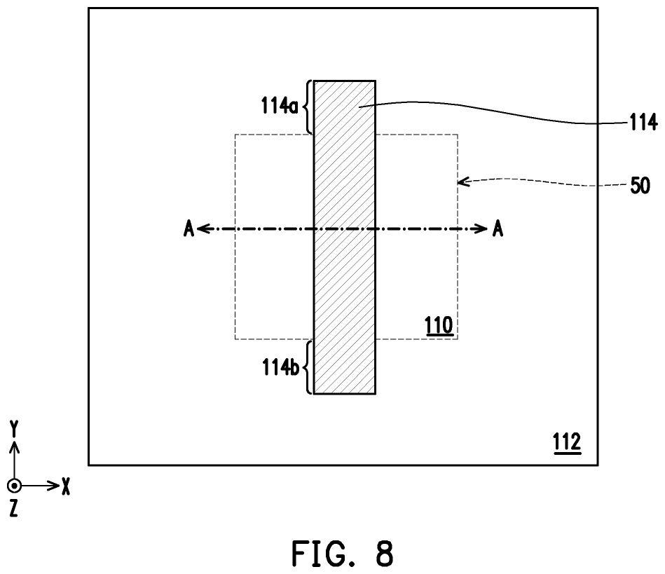

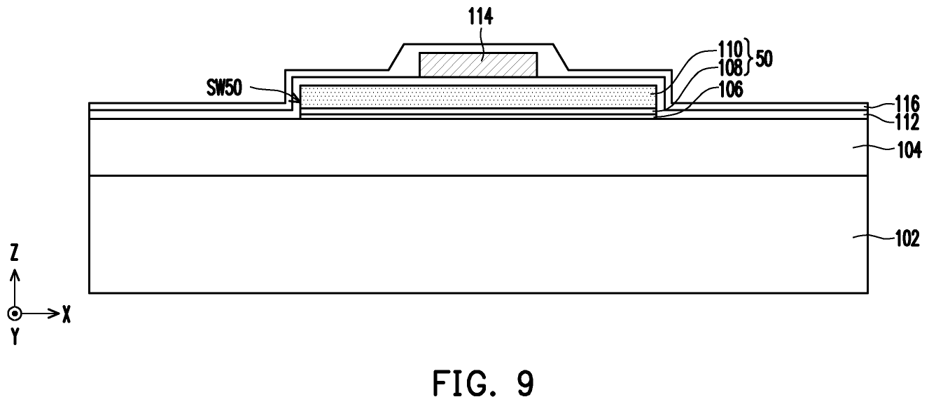

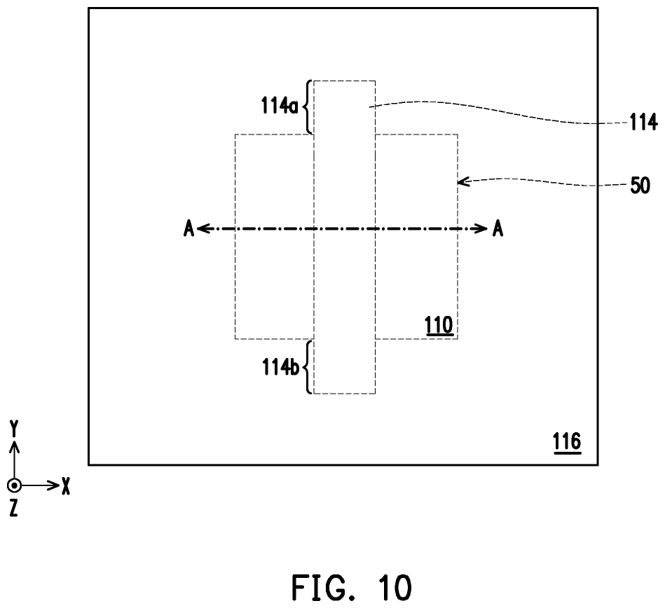

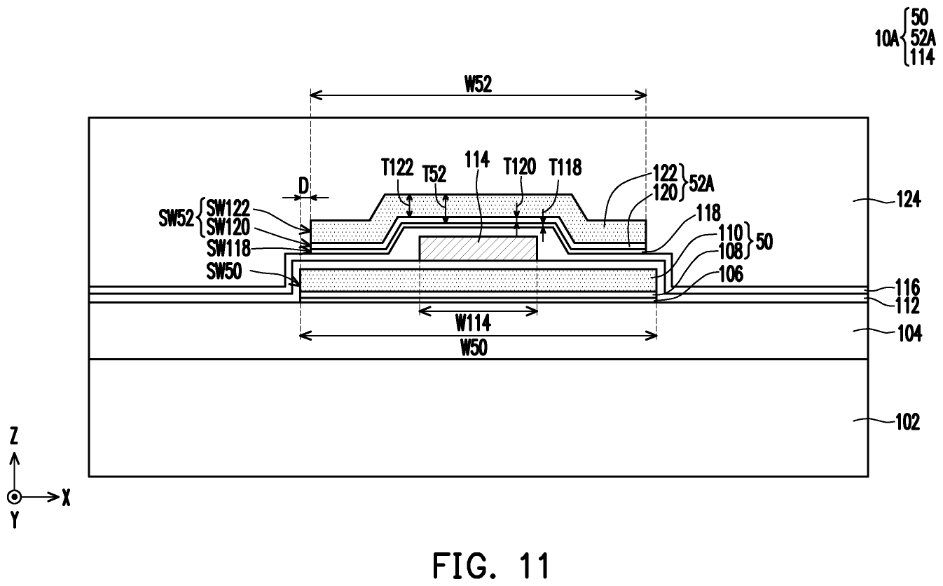

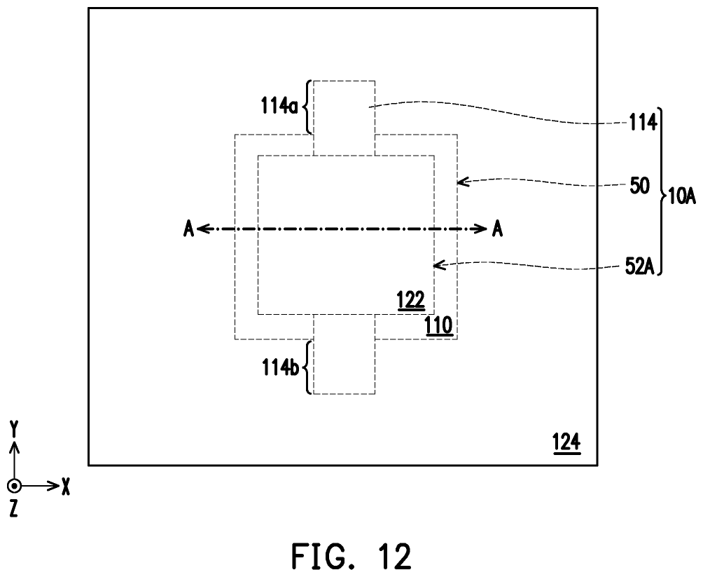

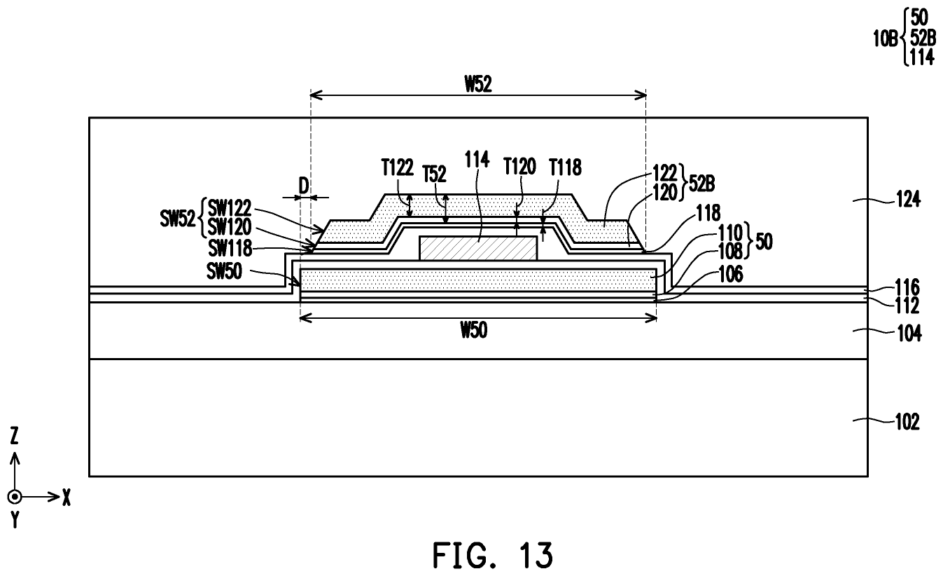

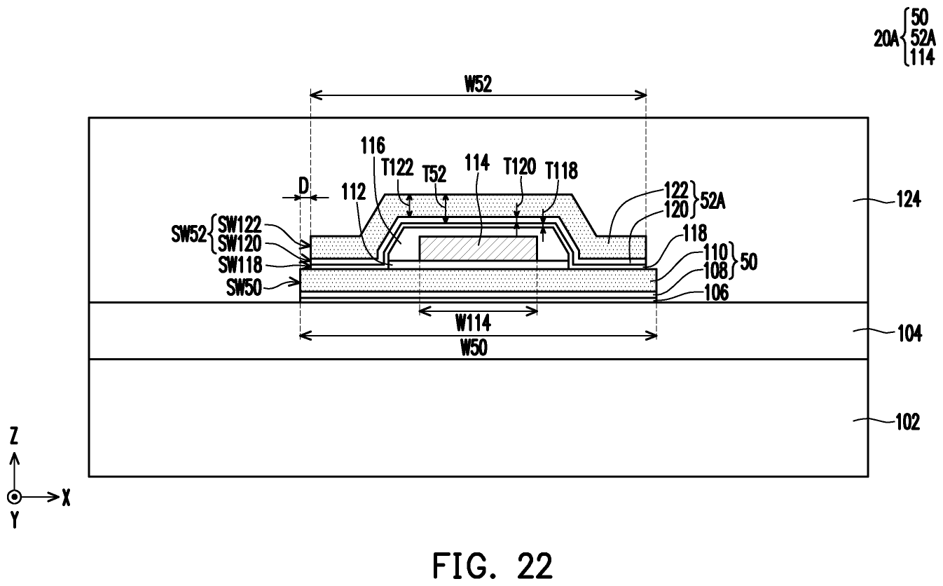

FIG. 1 to FIG. 12 are schematic plane or cross-sectional views of various stages in manufacturing an integrated voltage regulator (e.g., 10A) in accordance with some embodiments of the disclosure, where the schematic cross-sectional views of FIG. 1, FIG. 3, FIG. 5, FIG. 7, FIG. 9, and FIG. 11 are taken along with a line A-A depicted in the schematic plane views of FIG. 2, FIG. 4, FIG. 6. FIG. 8, FIG. 10, and FIG. 12, respectively. FIG. 13 through FIG. 18 are schematic, cross-sectional views (e.g., 10B, 10C, 10D, 10E, 10F, and 10G) respectively showing various embodiments of an integrated voltage regulator in accordance with the disclosure. FIG. 22 through FIG. 28 are schematic, cross-sectional views respectively showing various embodiments of an integrated voltage regulator (e.g., 20A, 20B, 20C, 20D, 20E, 20F, and 20G) in accordance with the disclosure. In some embodiments, the manufacturing method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

Referring to FIG. 1 and FIG. 2, in some embodiments, a base layer 102 is provided. In some embodiments, the base layer 102 may be a conductive layer, a semiconductor layer, an insulating layer, or a combination thereof. Alternatively, the base layer 102 may be any suitable carrier with sufficient support during manufacturing the integrated voltage regulator 10A (depicted in FIG. 11 and FIG. 12), such as reconstituted wafer, a glass substrate or a ceramic substrate. On the other hand, a thickness (e.g., in a direction Z) of the base layer 102 may be any suitable thickness that is thick enough to provide the sufficient support during manufacturing the integrated voltage regulator 10A (depicted in FIG. 11 and FIG. 12), the disclosure is not limited thereto.

For example, the conductive layer may be a layer formed of a metal or a metal alloy. Examples of the metal or metal alloy may be tungsten (W), cobalt (Co), copper (Cu), aluminum (Al), nickel (Ni), ruthenium (Ru), gold (Au), silver (Ag), molybdenum (Mo), manganese (Mg), zirconium (Zr), other suitable materials, and/or combinations thereof, where the conductive layer may be formed by deposition, electroplating, electroless plating, other suitable processes, and/or combinations thereof. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

For example, the semiconductor layer may be a layer formed of a semiconductor material. Examples of semiconductor material may be silicon (Si), germanium (Ge), silicon carbide (SiC), gallium arsenide (GaAs), gallium phosphide (GaP), indium phosphide (InP), indium arsenide (InAs), gallium arsenide phosphide (GaAsP), aluminum indium arsenide (AlInAs), aluminum gallium arsenide (AlGaAs), gallium indium arsenide (GalnAs), gallium indium phosphide (GalnP), gallium indium arsenide phosphide (GaInAsP), indium antimonide (InSb), silicon germanium (SiGe), and/or any other suitable semiconductor material, where the semiconductor layer may be formed by deposition.

For example, the insulating layer may be a layer formed of a dielectric material. Examples of the dielectric material may be an oxide, such as silicon oxide or silicon oxynitride; a nitride, silicon nitride or silicon carbon nitride; a polymer-based dielectric material, such as polyimide, epoxy resin, acrylic resin, phenol resin, benzocyclobutene (BCB), polybenzooxazole (PBO), and/or any other suitable polymer-based dielectric material, where the dielectric layer may be formed by deposition. The aforesaid deposition process may include, but may not be limited to, chemical vapor deposition (CVD) (such as plasma-enhanced CVD (PECVD) or the like), physical vapor deposition (PVD), atomic layer deposition (ALD), other suitable processes, and/or combinations thereof, for example. In some alternative embodiments, the dielectric material may include metal oxides or metal nitrides. Examples of the metal oxide includes ZrO₂, Gd₂O₃, HfO₂, BaTiO₃, Al₂O₃, LaO₂, TiO₂, Ta₂O₅, Y₂O₃, STO, BTO, BaZrO, HfZrO, HfLaO, HfTaO, HfTiO, or the like. Examples of the metal nitride includes TIN, TaN, WN, TiAIN, TaCN, or the like. In some further alternative embodiments, the dielectric material may include a silicate such as HfSiO, HfSiON, LaSiO, AlSiO, or the like.

In some embodiments, as shown in FIG. 1, a dielectric layer 104 is formed over the base layer 102. As shown in FIG. 1, the dielectric layer 104 may be globally formed on the base layer 102. In some embodiments, the dielectric layer 104 is in physical contact with the base layer 102. The dielectric layer 104 is a conformal layer of dielectric material, for example. In some embodiments, the dielectric layer 104 is an oxide layer, such as a silicon oxide layer or the like. However, the disclosure is not limited thereto, examples of the dielectric material may be an oxide, such as silicon oxide or silicon oxynitride; a nitride, silicon nitride or silicon carbon nitride. A thickness (e.g., in the direction Z) of the dielectric layer 104 may be any suitable thickness, the disclosure is not limited thereto.

It should be understood that the dielectric layer 104 may include one or more dielectric materials. The dielectric layer 104 may include a single-layer structure or a multilayer structure. The dielectric layer 104 may be formed to a suitable thickness by CVD (such as flowable chemical vapor deposition (FCVD), high-density plasma CVD (HDP-CVD) and sub-atmospheric CVD (SACVD) or the like) or other suitable methods. Herein, when a layer is described as conformal or conformally formed, it indicates that the layer has a substantially equal thickness extending along the region on which the layer is formed.

In some embodiments, as shown in FIG. 1, an adhesive material layer 106m is formed over the dielectric layer 104. As shown in FIG. 1, the adhesive material layer 106m may be globally formed on the dielectric layer 104. In some embodiments, the adhesive material layer 106m is in physical contact with the dielectric layer 104. For example, the dielectric layer 104 is disposed sandwiched between the base layer 102 and the adhesive material layer 106m. In such case, an illustrated top surface (not label) of the dielectric layer 104 is in direct contact with the adhesive material layer 106m, while an illustrated bottom surface (not label) of the dielectric layer 104 is in direct contact with the base layer 102, where the illustrated top surface of the dielectric layer 104 is opposite to the illustrated bottom surface of the dielectric layer 104 along the direction Z (may be referred to as a stacking direction).

The adhesive material layer 106m is a conformal layer, for example. The adhesive material layer 106m may be or may include titanium (Ti), tungsten (W), cobalt (Co), nickel (Ni), titanium nitride (TiN), a titanium tungsten alloy (TiW), vanadium (V), chromium (Cr), copper (Cu), a chromium copper alloy (CrCu), tantalum (Ta), tantalum nitride (TaN) or a composite layer or single layer of at least one of the above-mentioned materials. For a non-limiting example, the adhesive material layer is made of Ta. A thickness T106m (e.g., in the direction Z) of the adhesive material layer 106m may be approximately ranging from 1.0 nm to 10 nm, although other suitable thickness may alternatively be utilized. The adhesive material layer 106m may be formed to a suitable thickness by plating (such as electroless plating process), an evaporating process, a CVD process (such as FCVD, HDP-CVD and SACVD or the like) or other suitable methods. In the disclosure, the adhesive material layer 106m improves the bonding ability of a following deposited material and the underlying structure and prevents the following deposited material layer from diffusing into the underlying structure.

In some embodiments, a first material layer 108m and a second material layer 110m are sequentially formed over the adhesive material layer 106m, as shown in FIG. 1. The first material layer 108m may be globally formed on the adhesive material layer 106m, and the second material layer 110m may be globally formed on the first material layer 108m. In some embodiments, the first material layer 108m is in physical contact with the adhesive material layer 106m, and the second material layer 110m is in physical contact with the first material layer 108m. For example, the adhesive material layer 106m is sandwiched between the dielectric layer 104 and the first material layer 108m, and the first material layer 108m is sandwiched between the second material layer 110m and the adhesive material layer 106m. In such case, an illustrated top surface (not label) of the adhesive material layer 106m is in direct contact with the first material layer 108m, while an illustrated bottom surface (not label) of the adhesive material layer 106m is in direct contact with the dielectric layer 104, where the illustrated top surface of the adhesive material layer 106m is opposite to the illustrated bottom surface of the adhesive material layer 106m along the direction Z. On the other hand, an illustrated top surface (not label) of the first material layer 108m is in direct contact with the second material layer 110m, while an illustrated bottom surface (not label) of the first material layer 108m is in direct contact with the adhesive material layer 106m, where the illustrated top surface of the first material layer 108m is opposite to the illustrated bottom surface of the first material layer 108m along the direction Z.

In some embodiments, the first material layer 108m is an anti-ferromagnetic (AF) material layer. For example, the first material layer 108m may be or may include an anti-ferromagnetic material, such as IrMn, FeMn, NiO, Cr, or the like. The disclosure is not limited thereto. A thickness T108m (e.g., in the direction Z) of the first material layer 108m may be any suitable thickness, the disclosure is not limited thereto. A formation process of the first material layer 108m may be performed through PVD, CVD, ALD or the like, or other suitable methods.

In some embodiments, the second material layer 110m is a ferromagnetic (FM) material layer. For example, the second material layer 110m may be or may include a ferromagnetic material, such as CoFeB (where B <20at %), NiFe or the like. The disclosure is not limited thereto. A thickness T110m (e.g., in the direction Z) of the second material layer 110m may be any suitable thickness, the disclosure is not limited thereto. A formation process of the second material layer 110m may be performed through PVD, CVD, ALD or the like, or other suitable methods.

In some embodiments, a ratio of the thickness T108m of the first material layer 108m to the thickness T110m of the second material layer 110m is greater than or substantially equal to 4% and is less than or substantially equal to 20%, for example, being greater than or substantially equal to 4.0% and being less than or substantially equal to 16%.

Referring to FIG. 3 and FIG. 4, in some embodiments, the adhesive material layer 106m, the first material layer 108m and the second material layer 110m are patterned to form an adhesive layer 106 and a lower portion 50 of the IVR 10A (scc FIG. 11 and FIG. 12) disposed over the adhesive 106. For example, the lower portion 50 includes a first layer 108 and a second layer 110 disposed on the first layer 108, where the first layer 108 is disposed between (e.g., in contact with) the adhesive layer 106 and the second layer 110. As shown in FIG. 3, a sidewall SW106 of the adhesive layer 106, a sidewall SW108 of the first layer 108 and a sidewall SW110 of the second layer 110 may be substantially aligned. In some embodiments, the sidewall SW108 of the first layer 108 and the sidewall SW110 of the second layer 110 together constitute a sidewall SW50 of the lower portion 50. In some embodiments, the adhesive layer 106 and the lower portion including the first layer 108 and the second layer 110 may together be considered as a lower stacking unit of the IVR.

In some embodiments, a ratio of a thickness T108 of the first layer 108 to a thickness T110 of the second layer 110 is greater than or substantially equal to 4% and is less than or substantially equal to 20%, for example, being greater than or substantially equal to 4.0% and being less than or substantially equal to 16%. For example, a thickness T50 of the lower portion 50 is a sum of the thickness T108 of the first layer 108 and thickness T110 of the second layer 110. The thickness T50 (e.g., in the direction Z) of the lower portion 50 may be approximately ranging from 100 nm to 500 nm, although other suitable thickness may alternatively be utilized. For a non-limiting example, the thickness T108 of the first layer 108 is about 8.0 nm, and the thickness T110 of the second layer 110 is about 200 nm. The disclosure is not limited thereto. In some embodiments, as shown in FIG. 3, the lower portion 50 of the IVR 10A include a multi-layer structure including one layer of ferromagnetic material (e.g., the second layer 110) and one layer of anti-ferromagnetic material (e.g., the first layer 108). In such case, the lower portion 50 of the IVR 10A is referred to as a lower portion having a bi-layer structure. In some embodiments, in the plane view of FIG. 4, a shape of the lower portion 50 is in form of square shape. However, the disclosure is not limited thereto. The shape of the lower portion 50 may be in form of rectangular shape or any other suitable shape, in the plane view.

On the other hand, a thickness T106 (e.g., in the direction Z) of the adhesive layer 106 may be approximately ranging from 1.0 nm to 10 nm, although other suitable thickness may alternatively be utilized. For example, the thickness T106 of the adhesive layer 106 is about 3.0 nm. The disclosure is not limited thereto.

The patterning process may include suitable photolithography and etching techniques. For example, a first hardmask layer (not shown) may be formed over the second material layer 110m and then is patterned. The pattern of the first hardmask layer may then be transferred to the second material layer 110m, the first material layer 108m and the adhesive material layer 106m to form the second layer 110 and the first layer 108 of the lower portion 50 and the adhesive layer 106 using one or more etching techniques, such as dry etching and/or wet etching techniques. For example, the parts of the second material layer 110m, the first material layer 108m and the adhesive material layer 106m are not covered by the patterned first hardmask layer are removed, with the remaining portions of the second material layer 110m, the first material layer 108m and the adhesive material layer 106m forming the second layer 110 and the first layer 108 of the lower portion 50 and the adhesive layer 106, with sidewalls of the remaining portions defining the SW50 sidewall of the lower portion 50 and the sidewall SW106 of the adhesive layer 106. In some embodiments, the first hardmask layer may be formed of the photosensitive material such as a positive resist material or a negative resist material, that is suitable for a patterning process such as a photolithography process with a mask or a mask-less photolithography process (such as an electron-beam (e-beam) writing or an ion-beam writing). After forming the lower portion 50 and the adhesive layer 106, the first hardmask layer may be removed by acceptable ashing process and/or photoresist stripping process, such as using an oxygen plasma or the like, and the disclosure is not limited thereto. In some embodiments, more than one photolithography and etching sequence may be used.

In some embodiments, the lower portion 50 is disposed over the dielectric layer 104 over the base layer 102, where the adhesive layer 106 is disposed between the lower portion 50 and the dielectric layer 104. As illustrated in FIG. 3 and FIG. 4, on a vertical projection (e.g., on a X-Y plane) in the direction Z, a part of the dielectric layer 104 is accessibly revealed by the adhesive layer 106 and the lower portion 50 of the IVR 10A. A direction X may be different from a direction Y, and the directions X and Y may be different from the direction Z. For example, the direction Y and the direction X direction are perpendicular to each other, and the direction Y and the direction X are perpendicular to the direction Z. The directions Y and X may be referred to as lateral directions or horizontal directions, while the direction Z may alternatively be referred to as a vertical direction.

Referring to FIG. 5 and FIG. 6, in some embodiments, a dielectric layer 112 is formed over the lower portion 50 of the IVR 10A and the dielectric layer 104 exposed by the lower portion 50 of the IVR 10A. As shown in FIG. 5 and FIG. 6, the dielectric layer 112 may be globally formed on the lower portion 50 of the IVR 10A and may cover the dielectric layer 104 exposed by the lower portion 50 of the IVR 10A. In some embodiments, the dielectric layer 112 is in physical contact with an illustrated top surface and the sidewall SW110 of the second layer 110, the sidewall SW108 of the first layer 108, the sidewall SW106 of the adhesive layer 106 and the illustrated top surface of the dielectric layer 104 exposed therefrom. The dielectric layer 112 is a conformal layer of dielectric material including inorganic dielectrics or metal oxide/nitride, for example. Examples of the dielectric material may be an oxide, such as OCZT, Al₂O₃, silicon oxide or silicon oxynitride; a nitride, AlN, silicon nitride or silicon carbon nitride; or the like. A thickness (not labeled; e.g., in the direction Z) of the dielectric layer 112 may be approximately ranging from 0.1 μm to 10 μm, although other suitable thickness may alternatively be utilized.

Although a clear interface between the dielectric layer 112 and the dielectric layer 104 are shown in FIG. 5, the clear interface may not be presented if the dielectric layer 112 and the dielectric layer 104 being made of same material. In a non-limiting example, the material of the dielectric layer 112 is the same as the material of the dielectric layer 104. However, the disclosure is not limited thereto, the material of the dielectric layer 112 may be different from the material of the dielectric layer 104. It should be understood that the dielectric layer 112 may include one or more dielectric materials. The dielectric layer 112 may include a single-layer structure or a multilayer structure. The dielectric layer 112 may be formed to a suitable thickness by CVD (such as FCVD, HDP-CVD and SACVD or the like) or other suitable methods.

As shown in FIG. 5 and FIG. 6, in some embodiments, a conductive material layer 114m is formed over the dielectric layer 112. As shown in FIG. 5, the conductive material layer 114m may be globally formed on the dielectric layer 112. In some embodiments, the conductive material layer 114m is in physical contact with an illustrated top surface of the dielectric layer 112. In such case, the illustrated top surface (not label) of the dielectric layer 112 is in direct contact with the conductive material layer 114m, while an illustrated bottom surface (not label) of the dielectric layer 112 is in direct contact with the lower portion 50, the adhesive layer 106 and the dielectric layer 104, where the illustrated top surface of the dielectric layer 112 is opposite to the illustrated bottom surface of the dielectric layer 112 along the direction Z. The conductive material layer 114m may be a conformal layer formed of a metal or a metal alloy. Examples of the metal or metal alloy may be tungsten (W), cobalt (Co), copper (Cu), aluminum (Al), nickel (Ni), ruthenium (Ru), gold (Au), silver (Ag), molybdenum (Mo), manganese (Mg), zirconium (Zr), other suitable materials, and/or combinations thereof, where the conductive material layer 114m may be formed by deposition, electroplating, electroless plating, other suitable processes, and/or combinations thereof. For a non-limiting example, the conductive material layer is made of Cu. The disclosure is not limited thereto. A thickness T114m (e.g., in the direction Z) of the conductive material layer 114m may be approximately ranging from 15 μm to 20 μm, although other suitable thickness may alternatively be utilized.

Referring to FIG. 7 and FIG. 8, in some embodiments, the conductive material layer 114m is patterned to form a conductive layer 114 over the dielectric layer 112. As shown in FIG. 7, the conductive layer 114 may be physically separated and spacing apart from the lower portion 50 of the IVR 10A through the dielectric layer 112. In other words, along the direction Z, the dielectric layer 112 is disposed between (e.g., in physical contact with) the conductive layer 114 and the lower portion 50. For example, in a cross-sectional view in the direction Z, the conductive layer 114 is overlapped with the lower portion 50 of the IVR 10A. On the other hand, in the X-Y plane, the conductive layer 114 is overlapped with the lower portion 50 of the IVR 10A and further extends across the lower portion 50 of the IVR 10A. As shown in the plane view of FIG. 8, two end regions 114a and 114b of the conductive layer 114 may be offset from (e.g., not overlapped with) the lower portion 50 of the IVR 10A for electrical connections to other components (e.g., electrical connections for input power and output power to the IVR 10A). The input power of the IVR 10A may be provided to the IVR 10A by electrically coupling (e.g., physically contacting) one of the two end regions 114a and 114b and an conductive feature (with the input power, such as an input voltage) underlying or overlying the one of the two end regions 114a and 114b, and the output power of the IVR 10A may be provided from the IVR 10A by electrically coupling (e.g., physically contacting) other one of the two end regions 114a and 114b and an conductive feature (receiving the output power, such as an output voltage) underlying or overlying the other one of the two end regions 114a and 114b. In other words, the IVR 10A may be a voltage regulator that supplies and/or controls a voltage supplied to the respective electronic component(s) (e.g., a logic component, a memory component, a capacitor, a resistor, a diode, a photodiode, a fuse, other suitable electronic component, and the like).

A thickness T114 (e.g., in the direction Z) of the conductive layer 114 may be approximately ranging from 15 μm to 20 μm, although other suitable thickness may alternatively be utilized. A width W114 of the conductive layer 114 may be approximately ranging from 50 μm to 80 μm, although other suitable width may alternatively be utilized. The disclosure is not limited thereto. As illustrated in FIG. 7, for example, a width W50 of the lower portion is greater than the width W114 of the conductive layer 114. The conductive layer 114 may be referred to as a conductive feature of the IVR 10A. In some embodiments, in the plane view of FIG. 8, a shape of the conductive layer 114 is in form of strip shape. However, the disclosure is not limited thereto. The shape of the conductive layer 114 may be in form of spiral shape or any other suitable shape, in the plane view.

The patterning process may include suitable photolithography and etching techniques. For example, a second hardmask layer (not shown) may be formed over the conductive material layer 114m and then is patterned. The pattern of the second hardmask layer may then be transferred to the conductive material layer 114m to form the conductive layer 114 using one or more etching techniques, such as dry etching and/or wet etching techniques. For example, the parts of the conductive material layer 114m are not covered by the patterned second hardmask layer are removed, with the remaining portions of the conductive material layer 114m forming the conductive layer 114. In some embodiments, the second hardmask layer may be formed of the photosensitive material such as a positive resist material or a negative resist material, that is suitable for a patterning process such as a photolithography process with a mask or a mask-less photolithography process (such as an electron-beam (e-beam) writing or an ion-beam writing). After forming the conductive layer 114, the second hardmask layer may be removed by acceptable ashing process and/or photoresist stripping process, such as using an oxygen plasma or the like, and the disclosure is not limited thereto. In some embodiments, more than one photolithography and etching sequence may be used. The formation and material of the second hardmask layer may be the same as or different from the formation and material of the first hardmask layer. As shown in FIG. 7 and FIG. 8, the dielectric layer 112 are partially exposed by the conductive layer 114.

Referring to FIG. 9 and FIG. 10, in some embodiments, a dielectric layer 116 is formed over the conductive layer 114 and the dielectric layer 112 exposed by the conductive layer 114. As shown in FIG. 9 and FIG. 10, the dielectric layer 116 may be globally formed on the conductive layer 114 and may cover the dielectric layer 112 exposed by the conductive layer 114. In some embodiments, the dielectric layer 116 is in physical contact with an illustrated top surface and a sidewall of the conductive layer 114 and the illustrated top surface of the dielectric layer 112 exposed therefrom. The dielectric layer 116 is a conformal layer of dielectric material including inorganic dielectrics or metal oxide/nitride, for example. Examples of the dielectric material may be an oxide, such as OCZT, Al₂O₃, silicon oxide or silicon oxynitride; a nitride, AlN, silicon nitride or silicon carbon nitride; or the like. A thickness (not labeled; e.g., in the direction Z) of the dielectric layer 116 may be approximately ranging from 0.1 μm to 10 μm, although other suitable thickness may alternatively be utilized.

Although a clear interface between the dielectric layer 116 and the dielectric layer 112 are shown in FIG. 9, the clear interface may not be presented if the dielectric layer 116 and the dielectric layer 112 being made of same material. In a non-limiting example, the material of the dielectric layer 116 is the same as the material of the dielectric layer 104 and/or the dielectric layer 112. However, the disclosure is not limited thereto, the material of the dielectric layer 116 may be different from the material of the dielectric layer 104 and/or the dielectric layer 112. It should be understood that the dielectric layer 116 may include one or more dielectric materials. The dielectric layer 116 may include a single-layer structure or a multilayer structure. The dielectric layer 116 may be formed to a suitable thickness by CVD (such as FCVD, HDP-CVD and SACVD or the like) or other suitable methods.

Referring to FIG. 11 and FIG. 12, in some embodiments, an adhesive layer 118 and an upper portion 52A of the IVR 10A are sequentially formed over the dielectric layer 116, and a dielectric layer 124 is then formed over the upper portion 52A and covers the dielectric layer 116 accessibly revealed therefrom. For example, the upper portion 52A includes a first layer 120 and a second layer 122 stacked on the first layer 120, where the first layer 120 is stacked on the adhesive layer 118. In other words, the dielectric layer 116 may be sandwiched between the conductive layer 114 and the adhesive layer 118, the adhesive layer 118 may be sandwiched between the dielectric layer 116 and the first layer 120, the first layer 120 may be sandwiched between the adhesive layer 118 and the second layer 122, and the second layer 122 is sandwiched between the first layer 120 and the dielectric layer 124, as shown in FIG. 11. In such case, an illustrated top surface (not label) of the adhesive layer 118 is in direct contact with the first layer 120, while an illustrated bottom surface (not label) of the adhesive layer 118 is in direct contact with the dielectric layer 116, where the illustrated top surface of the adhesive layer 118 is opposite to the illustrated bottom surface of the adhesive layer 118 along the direction Z. On the other hand, an illustrated top surface (not label) of the first layer 120 is in direct contact with the second layer 122, while an illustrated bottom surface (not label) of the first layer 120 is in direct contact with the adhesive layer 118, where the illustrated top surface of the first layer 120 is opposite to the illustrated bottom surface of the first layer 120 along the direction Z. In addition, an illustrated top surface (not label) of the second layer 122 is in direct contact with the dielectric layer 124, while an illustrated bottom surface (not label) of the second layer 122 is in direct contact with the first layer 120, where the illustrated top surface of the second layer 122 is opposite to the illustrated bottom surface of the second layer 122 along the direction Z.

The dielectric layer 124 may be in physical contact with an illustrated top surface and a sidewall SW122 of the second layer 122, a sidewall SW120 of the first layer 120, a sidewall SW118 of the dielectric layer 118, and the illustrated top surface of the dielectric layer 116 exposed therefrom. In some embodiments, the dielectric layer 124 is an oxide layer, such as a silicon oxide layer or the like. However, the disclosure is not limited thereto, examples of the dielectric material may be an oxide, such as silicon oxide or silicon oxynitride; a nitride, silicon nitride or silicon carbon nitride. Although a clear interface between the dielectric layer 124 and the dielectric layer 116 are shown in FIG. 9, the clear interface may not be presented if the dielectric layer 124 and the dielectric layer 116 being made of same material. In a non-limiting example, the material of the dielectric layer 124 is the same as the material of the dielectric layer 104, the dielectric layer 112 and/or the dielectric layer 116. However, the disclosure is not limited thereto, the material of the dielectric layer 124 may be different from the material of the dielectric layer 104, the dielectric layer 112 and/or the dielectric layer 116.

It should be understood that the dielectric layer 124 may include one or more dielectric materials. The dielectric layer 124 may include a single-layer structure or a multilayer structure. The dielectric layer 124 may be formed to a suitable thickness by CVD (such as FCVD, HDP-CVD and SACVD or the like) or other suitable methods. A polarization process may be optionally performed on the dielectric layer 124 so that an illustrated top surface of the dielectric layer 124 may be substantially flat and planar, as shown in FIG. 11. The formation and the material of each of the adhesive layer 118, the first layer 120 and the second layer 122 are substantially identical to or similar to the formation and the material of each of the adhesive layer 106, the first layer 108 and the second layer 110, respectively; and thus, are not repeated herein for simplicity. Up to here, the IVR 10A is manufactured, where the conductive layer 114 is surrounded by the lower portion 50 and the upper portion 52A.

In some embodiments, a thickness T118 (e.g., in the direction Z) of the adhesive layer 118 may be approximately ranging from 1.0 nm to 10 nm, although other suitable thickness may alternatively be utilized. For example, the thickness T118 of the adhesive layer 118 is about 3.0 nm, however the disclosure is not limited thereto. In some embodiments, a ratio of a thickness T120 of the first layer 120 to a thickness T122 of the second layer 122 is greater than or substantially equal to 4% and is less than or substantially equal to 20%, for example, being greater than or substantially equal to 4.0% and being less than or substantially equal to 16%. For example, a thickness T52 of the upper portion 52A is a sum of the thickness T120 of the first layer 120 and thickness T122 of the second layer 122. The thickness T52 (e.g., in the direction Z) of the upper portion 52A may be approximately ranging from 100 nm to 500 nm, although other suitable thickness may alternatively be utilized. For a non-limiting example, the thickness T120 of the first layer 120 is about 8.0 nm, and the thickness T122 of the second layer 122 is about 200 nm. The disclosure is not limited thereto. In some embodiments, as shown in FIG. 11, the upper portion 52A of the IVR 10A include a multi-layer structure including one layer of ferromagnetic material (e.g., the second layer 122) and one layer of anti-ferromagnetic material (e.g., the first layer 120). In such case, the upper portion 52A of the IVR 10A is referred to as an upper portion having a bi-layer structure. Owing to the multi-layer structure (e.g., the bi-layer structures) of the upper portion 52A and the lower portion 50 included in the IVR 10A, the stack of the anti-ferromagnetic layer and the ferromagnetic layer undergo the exchange coupling of magnetic dipole during the operation, which promotes anisotropy field increment and then leads to an increasement in the operation frequency of the IVR 10A (e.g., boosted to be greater than 100MGz), thereby improving the performance of a semiconductor device equipped with the IVR 10A.

In some embodiments, in the plane view of FIG. 12, a shape of the upper portion 52A is in form of square shape. However, the disclosure is not limited thereto. The shape of the upper portion 52A may be in form of rectangular shape or any other suitable shape, in the plane view. Similarly, as shown in the plane view of FIG. 12, two end regions 114a and 114b of the conductive layer 114 may be also offset from (e.g., not overlapped with) the upper portion 52A of the IVR 10A for electrical connections to other components (e.g., electrical connections for input power and output power to the IVR 10A).

As shown in FIG. 11, the sidewall SW118 of the adhesive layer 118, the sidewall SW120 of the first layer 120 and the sidewall SW122 of the second layer 122 may be substantially aligned. In some embodiments, the sidewall SW120 of the first layer 120 and the sidewall SW122 of the second layer 122 together constitute a sidewall SW52 of the upper portion 52A. In some embodiments, the adhesive layer 118 and the upper portion including the first layer 120 and the second layer 122 may together be considered as an upper stacking unit of the IVR. As illustrated in FIG. 11, for example, the width W114 of the conductive layer 114 is less than a width W52 of the upper portion 52A of the IVR 10A. The sidewall SW52 of the upper portion 52A indented from the sidewall SW50 of the lower portion 50. In some embodiments, for the IVR 10A, the width W52 of the upper portion 52A is less than the width W50 of the lower portion 50 by a distance D. The distance D may be approximately ranging from 3.0 μm to 5.0 μm, although other suitable distance may alternatively be utilized. Owing to the configuration (e.g., the presence of the distance D), the inductance of the IVR 10A is increased, so that an overall occupied area of the IVR 10A can be reduced (if with the same value of the inductance), thereby further improving the performance of the semiconductor device equipped with the IVR 10A.

In embodiments of the IVR 10A, the sidewall SW52 of the upper portion 52A is a substantially vertical sidewall, and the sidewall SW118 of the adhesive layer 118 is a substantially vertical sidewall being aligned with the sidewall SW52 of the upper portion 52, as shown in the cross-sectional view of FIG. 11. However, the disclosure is not limited thereto. Alternatively, the sidewall SW118 of the adhesive layer 118 underlying the upper portion 52A may be a slant sidewall, where the sidewall SW118 has an innermost edge being connecting the sidewall SW52 of the upper portion 52A.

In the embodiments of the IVR 10A, the conductive layer 114 are enclosed by the dielectric layers 112 and 116, where the dielectric layer 112 and the dielectric layer 116 respectively extend from the conductive layer 114 toward the sidewall SW52 of the upper portion 52A and the SW50 of the lower portion 50. For example, as shown in FIG. 11, the dielectric layer 112 and the dielectric layer 116 respectively extend beyond the sidewall SW52 of the upper portion 52A and the SW50 of the lower portion 50. In such cases, for the IVR 10A, through the dielectric layer 112 and the dielectric layer 116, the upper stacking unit (including the upper portion 52A and the adhesive layer 118) is separated from the lower stacking unit (including lower portion 50 and the adhesive layer 106). However, the disclosure is not limited thereto; alternatively, the IVR 20A of FIG. 22 is similar to the IVR 10A of FIG. 11 and FIG. 12; the difference is that, in the IVR 20A of FIG. 22, the upper stacking unit (including the upper portion 52A and the adhesive layer 118) is in physical contact with (e.g., in direct contact with) the lower stacking unit (including lower portion 50 and the adhesive layer 106). In such alternative embodiments, sidewalls of the dielectric layer 112 and the dielectric layer 116 are covered by the upper stacking unit. For example, the conductive layer 114 is completely enclosed by the dielectric layer 112 and the dielectric layer 116, where the conductive layer 114 is completely enclosed by the upper stacking unit and the lower stacking unit of the IVR 20A.

In a non-limiting example, the dielectric layer 112, the dielectric layer 116 and the adhesive layer 118) may be patterned in different patterning processes. Or, the dielectric layer 112 and the dielectric layer 116 may be patterned in the same patterning processes, and the adhesive layer 118 may be patterned in other patterning process. Or alternatively, the dielectric layer 112, the dielectric layer 116 and the adhesive layer 118) may be patterned in the same patterning process.

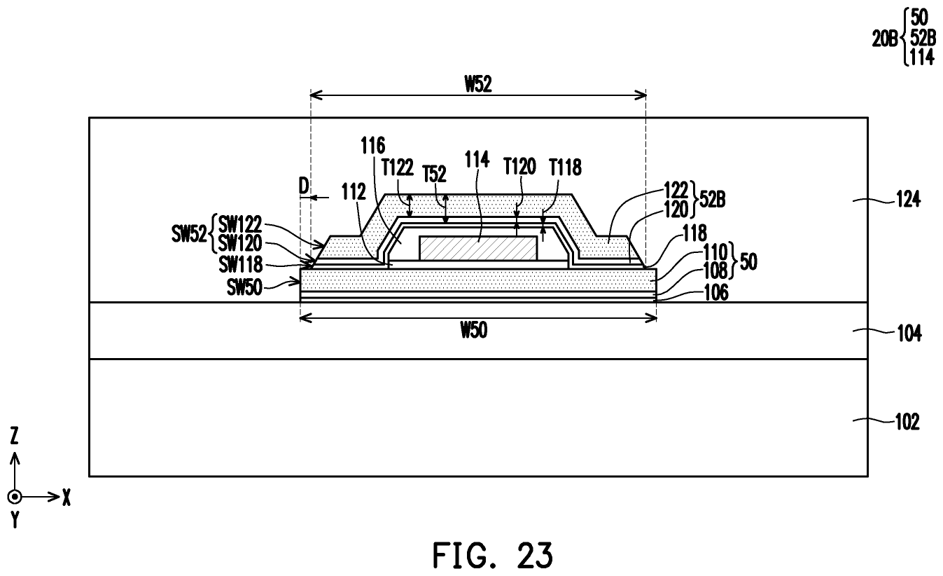

In some embodiments, a IVR 10B of FIG. 13 is similar to the IVR 10A of FIG. 11 and FIG. 12; the difference is that, in the IVR 10B of FIG. 13, an upper portion 52B is adopted, instead of the upper portion 52A. Referring to FIG. 13, in some embodiments, the IVR 10B includes a conductive layer 114, a lower portion 50 underlying the conductive layer 114, and an upper portion 52B overlying the conductive layer 114 and the lower portion 50, where the conductive layer 114 is surrounded by and separated from the lower portion 50 and the upper portion 52B. The formation and material of each of the conductive layer 114 and the lower portion 50 have been discussed in FIG. 1 through FIG. 8, and the formation and material of the upper portion 52B are substantially identical to or similar to the formation and material of the upper portion 52A described in FIG. 11 and FIG. 12, and thus are not repeated therein for brevity. As shown in the cross-sectional view of FIG. 13, a sidewall SW52 of the upper portion 52B may be a slant sidewall. For example, the sidewall SW52 of the upper portion 52B is a continuously slant sidewall connecting an illustrated top surface of the second layer 122 and the illustrated bottom surface of the first layer 120. In some embodiments, a sidewall SW118 of the adhesive layer 118 underlying the upper portion 52B has a slant sidewall having a common slope with the sidewall SW52 of the upper portion 52B, as shown in FIG. 13. However, the disclosure is not limited thereto, alternatively, the sidewall SW118 of the adhesive layer 118 underlying the upper portion 52B has a substantially vertical sidewall being aligned with an outermost edge of the sidewall SW52 (e.g., the slant sidewall) of the upper portion 52B. Similarly, the IVR 20B of FIG. 23 is similar to the IVR 10B of FIG. 13; the difference is that, in the IVR 20B of FIG. 23, the upper stacking unit (including the upper portion 52B and the adhesive layer 118) is in physical contact with (e.g., in direct contact with) the lower stacking unit (including lower portion 50 and the adhesive layer 106). In such alternative embodiments, sidewalls of the dielectric layer 112 and the dielectric layer 116 are covered by the upper stacking unit. For example, the conductive layer 114 is completely enclosed by the dielectric layer 112 and the dielectric layer 116, where the conductive layer 114 is completely enclosed by the upper stacking unit and the lower stacking unit of the IVR 20B.

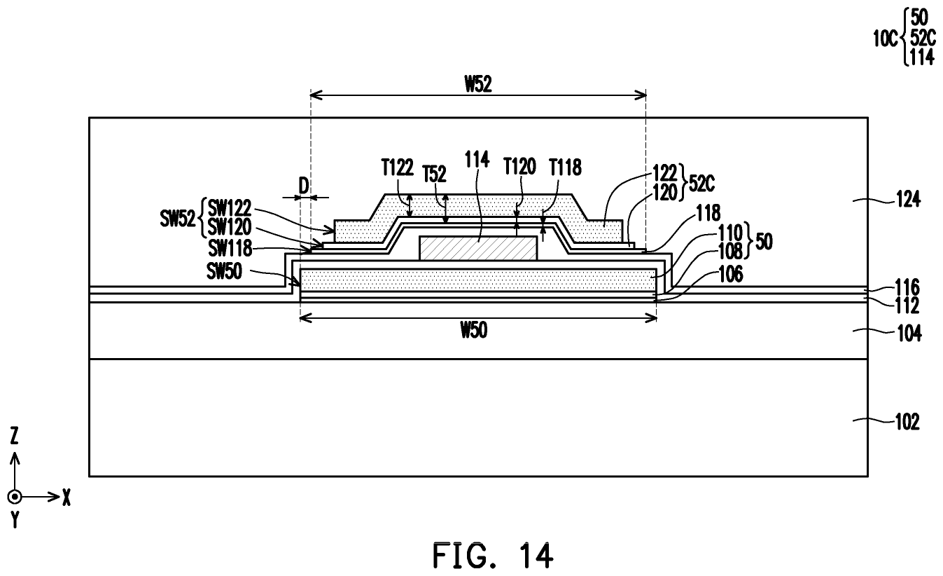

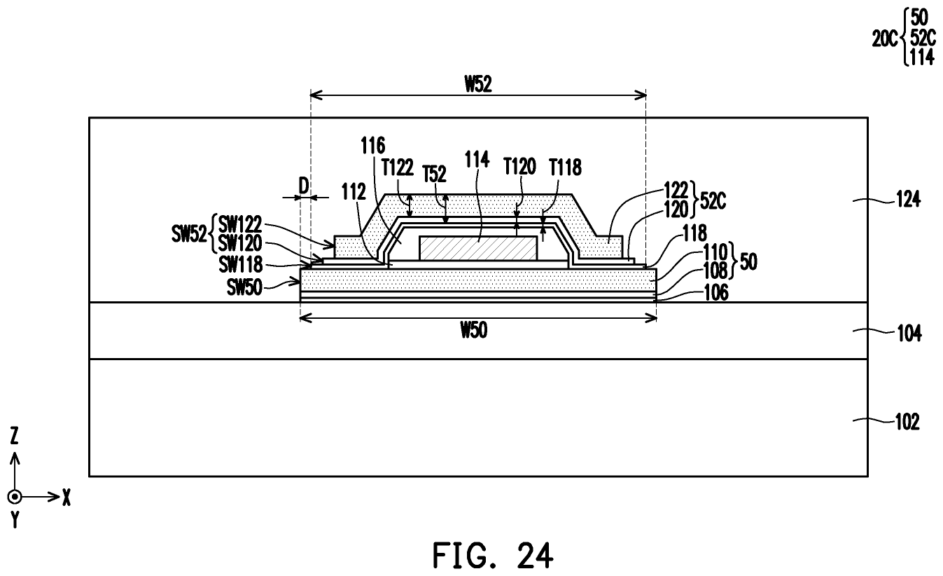

In some alternative embodiments, a IVR 10C of FIG. 14 is similar to the IVR 10A of FIG. 11 and FIG. 12; the difference is that, in the IVR 10C of FIG. 14, an upper portion 52C is adopted, instead of the upper portion 52A. Referring to FIG. 14, in some embodiments, the IVR 10C includes a conductive layer 114, a lower portion 50 underlying the conductive layer 114, and an upper portion 52C overlying the conductive layer 114 and the lower portion 50, where the conductive layer 114 is surrounded by and separated from the lower portion 50 and the upper portion 52C. The formation and material of each of the conductive layer 114 and the lower portion 50 have been discussed in FIG. 1 through FIG. 8, and the formation and material of the upper portion 52C are substantially identical to or similar to the formation and material of the upper portion 52A described in FIG. 11 and FIG. 12, and thus are not repeated therein for brevity. As shown in the cross-sectional view of FIG. 14, a sidewall SW52 of the upper portion 52C may be in a form of step-shape, where a sidewall SW120 of the first layer 120 and a sidewall SW122 of the second layer 122 are substantially vertical sidewalls and offset from each other. For example, the sidewall SW122 of the second layer 122 is indented from the sidewall SW120 of the first layer 120, so that a portion of the first layer 120 is accessibly revealed by the second layer 122 and is covered by the dielectric layer 124. In some embodiments, a sidewall SW118 of the adhesive layer 118 underlying the upper portion 52B has a substantially vertical sidewall being offset from the sidewall SW120 of the first layer 120 and the sidewall SW122 of the second layer 122. As shown in FIG. 14, the sidewall SW120 of the first layer 120 is indented from the sidewall SW118 of the adhesive layer 118, and thus a portion of the adhesive layer 118 is accessibly revealed by the first layer 120 and the second layer 122 and is covered by the dielectric layer 124. However, the disclosure is not limited thereto, alternatively, the sidewall SW118 of the adhesive layer 118 underlying the upper portion 52C may be a slant sidewall being distant from an outermost edge of the sidewall SW52 of the upper portion 52C. Similarly, the IVR 20C of FIG. 24 is similar to the IVR 10C of FIG. 14; the difference is that, in the IVR 20C of FIG. 24, the upper stacking unit (including the upper portion 52C and the adhesive layer 118) is in physical contact with (e.g., in direct contact with) the lower stacking unit (including lower portion 50 and the adhesive layer 106). In such alternative embodiments, sidewalls of the dielectric layer 112 and the dielectric layer 116 are covered by the upper stacking unit. For example, the conductive layer 114 is completely enclosed by the dielectric layer 112 and the dielectric layer 116, where the conductive layer 114 is completely enclosed by the upper stacking unit and the lower stacking unit of the IVR 20C.

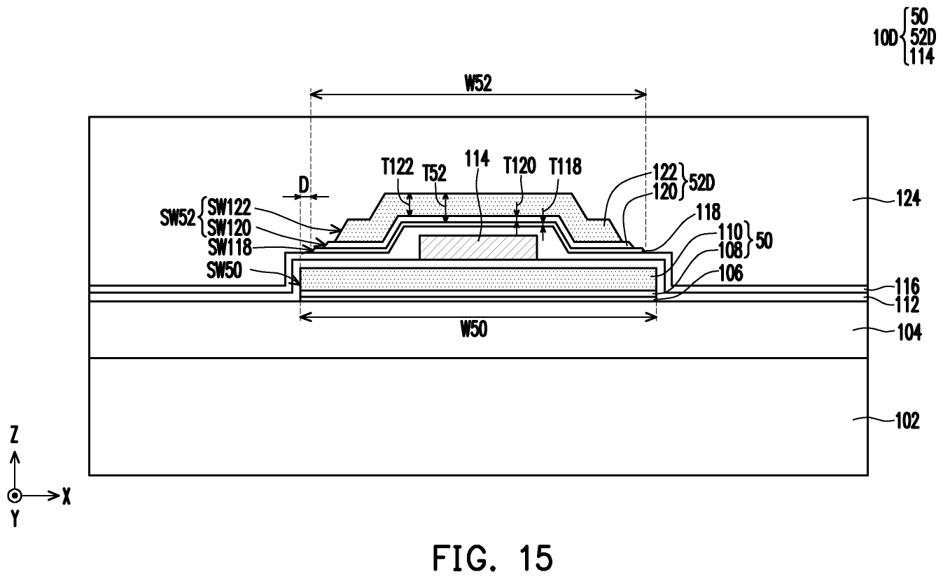

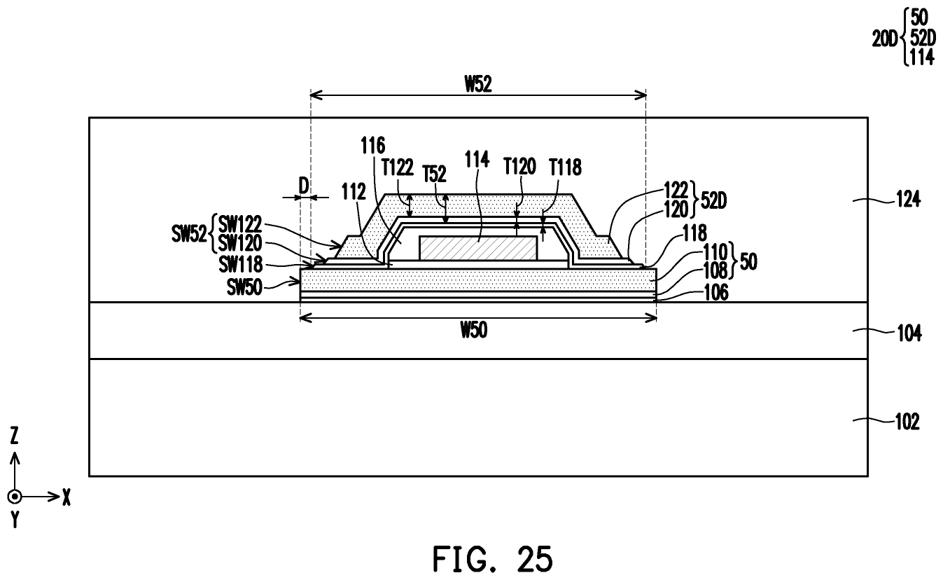

In some alternative embodiments, a IVR 10D of FIG. 15 is similar to the IVR 10A of FIG. 11 and FIG. 12; the difference is that, in the IVR 10D of FIG. 15, an upper portion 52D is adopted, instead of the upper portion 52A. Referring to FIG. 15, in some embodiments, the IVR 10 includes a conductive layer 114, a lower portion 50 underlying the conductive layer 114, and an upper portion 52D overlying the conductive layer 114 and the lower portion 50, where the conductive layer 114 is surrounded by and separated from the lower portion 50 and the upper portion 52D. The formation and material of each of the conductive layer 114 and the lower portion 50 have been discussed in FIG. 1 through FIG. 8, and the formation and material of the upper portion 52D are substantially identical to or similar to the formation and material of the upper portion 52A described in FIG. 11 and FIG. 12, and thus are not repeated therein for brevity. As shown in the cross-sectional view of FIG. 15, a sidewall SW52 of the upper portion 52C may be in a form of step-shape, where a sidewall SW120 of the first layer 120 and a sidewall SW122 of the second layer 122 are slant sidewalls and offset from each other. For example, the sidewall SW122 of the second layer 122 is indented from the sidewall SW120 of the first layer 120, so that a portion of the first layer 120 is accessibly revealed by the second layer 122 and is covered by the dielectric layer 124. In some embodiments, a sidewall SW118 of the adhesive layer 118 underlying the upper portion 52B has a slant sidewall being offset from the sidewall SW120 of the first layer 120 and the sidewall SW122 of the second layer 122. As shown in FIG. 15, the sidewall SW120 of the first layer 120 is indented from the sidewall SW118 of the adhesive layer 118, and thus a portion of the adhesive layer 118 is accessibly revealed by the first layer 120 and the second layer 122 and is covered by the dielectric layer 124. However, the disclosure is not limited thereto, alternatively, the sidewall SW118 of the adhesive layer 118 underlying the upper portion 52C may be a substantially vertical sidewall being distant from an outermost edge of the sidewall SW52 of the upper portion 52D. Similarly, the IVR 20D of FIG. 25 is similar to the IVR 10D of FIG. 15; the difference is that, in the IVR 20D of FIG. 25, the upper stacking unit (including the upper portion 52D and the adhesive layer 118) is in physical contact with (e.g., in direct contact with) the lower stacking unit (including lower portion 50 and the adhesive layer 106). In such alternative embodiments, sidewalls of the dielectric layer 112 and the dielectric layer 116 are covered by the upper stacking unit. For example, the conductive layer 114 is completely enclosed by the dielectric layer 112 and the dielectric layer 116, where the conductive layer 114 is completely enclosed by the upper stacking unit and the lower stacking unit of the IVR 20D.

However, the disclosure is not limited thereto. In addition to or alternatively, the above-mentioned modifications of the upper portion 52A may also adopted by the lower portion 50.

On the other hand, in embodiments of the IVR 10A, the upper portion 52A and the lower portion 50 individually include a single bi-layer structure. For example, the lower portion 50 includes the bi-layer structure of the first layer 108 and the second layer 110 stacked on the first layer 108, and the upper portion 52A includes the bi-layer structure of the first layer 120 and the second layer 122 stacked on the first layer 120. However, the disclosure is not limited thereto, at least one of the upper portion and the lower portion of the IVR in the disclosure may include a multi-layer structure including a stack of bi-layers.

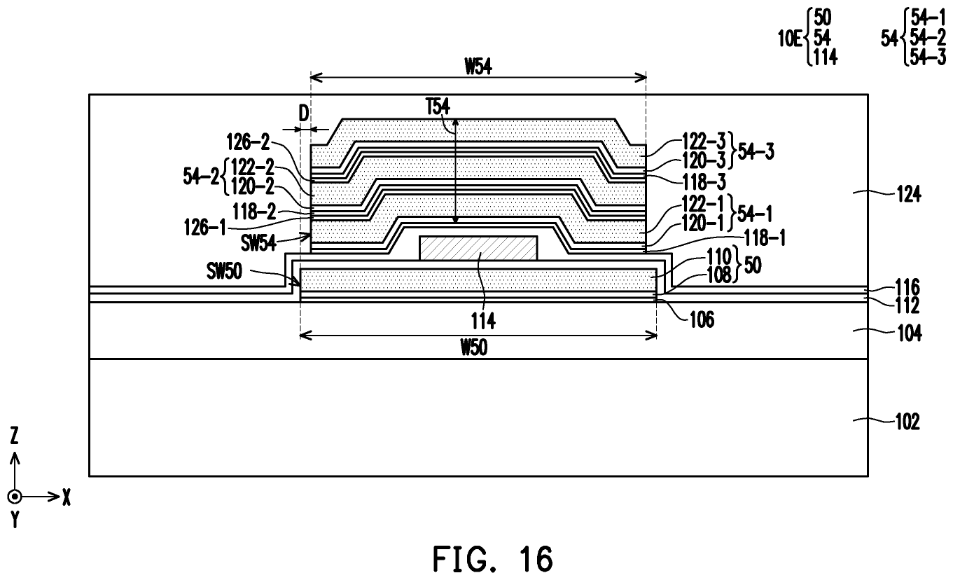

In some embodiments, a IVR 10E of FIG. 16 is similar to the IVR 10A of FIG. 11 and FIG. 12; the difference is that, in the IVR 10E of FIG. 16, an upper portion 54 is adopted, instead of the upper portion 52A. Referring to FIG. 16, in some embodiments, the IVR 10E includes a conductive layer 114, a lower portion 50 underlying the conductive layer 114, and an upper portion 54 overlying the conductive layer 114 and the lower portion 50, where the conductive layer 114 is surrounded by and separated from the lower portion 50 and the upper portion 54. As shown in FIG. 16, the upper portion 54 may include a plurality of sub-layers (e.g., upper portions 54-1, 54-2, and 54-3) sequentially stacked on one another, and each of the sub-layers (e.g., 54-1, 54-2, 54-3) may include a bi-layer structure having a first layer (e.g., 120-1, 120-2, 120-3) and a second layer (e.g., 122-1, 122-2, 122-3) stacked on the first layer (e.g., 120-1, 120-2, 120-3). For example, the sub-layer (e.g., 54-1) is separated from the sub-layer (e.g., 54-2) through a dielectric layer 126-1, and the sub-layer (e.g., 54-2) is separated from the sub-layer (e.g., 54-3) through a dielectric layer 126-2. Owing to the presences of the dielectric layers 126-1, 126-2, the eddy current loss can be suppressed, thereby ensuring the performance of the IVR 10E. The dielectric layers 126-1, 126-2 may be referred to as isolation layers or isolation structures.

In some embodiments, an adhesive layer 118-1 is disposed between the dielectric layer 116 and the sub-layer (e.g., 54-1), an adhesive layer 118-2 is disposed between the sub-layer (e.g., 54-1) and the sub-layer (e.g., 54-2), and an adhesive layer 118-3 is disposed between the sub-layer (e.g., 54-2) and the sub-layer (e.g., 54-3). Owing to the adhesive layers 118-1, 118-2 and 118-3, the delamination between the sub-layers (e.g., 54-1, 54-2, and 54-3) and between the dielectric layer 116 and the upper portion 54 can be suppressed, thereby ensuring the reliability of the IVR 10E. The formations and materials of the conductive layer 114 and the lower portion 50 have been discussed in FIG. 1 through FIG. 8, the formations and materials of the adhesive layers (e.g., 118-1, 118-2, 118-3), the first layers (e.g., 120-1, 120-2, 120-3) and the second layers (e.g., 122-1, 122-2, 122-3) are substantially identical to or similar to the formations and materials of the adhesive layer 118, the first layer 120 and the second layer 122 as previously described in FIG. 11 and FIG. 12, and the formations and materials of the dielectric layer (126-1, 126-2) are substantially identical to or similar to the formations and materials of the dielectric layers 104, 112, 116 and/or 124 as previously described in FIG. 1, FIG. 2 and FIG. 9 through FIG. 12; thus, are not repeated therein for brevity.

As shown in the cross-sectional view of FIG. 16, a sidewall SW54 of the upper portion 54 is constituted by sidewalls (not labeled) of the sub-layers (e.g., 54-1, 54-2, 54-3). The sidewall SW54 of the upper portion 54 is a substantially vertical sidewall, for example. However, the disclosure is not limited thereto; alternatively, the sidewall SW54 of the upper portion 54 may adopt the modifications of the upper portion 52A as previously described in FIG. 13 through FIG. 15. In some embodiments, one adhesive layer (e.g., 118-1, 118-2, 118-3, or so on) and a respective one of the sub-layers (e.g., 54-1, 54-2, 54-3, or so on) including the first layer (e.g., 120-1, 120-2, 120-3 or so on) and the second layer (e.g., 122-1, 122-2, 122-3, or so on) may together be considered as one upper stacking unit of the IVR.

In some embodiments, for each sub-layer (e.g., 54-1, 54-2, 54-3), a ratio of a thickness (e.g., T120) of the first layer 120-1, 120-2, 120-3 to a thickness (e.g., T122) of the second layer 122-1, 122-2, 122-3 is greater than or substantially equal to 4% and is less than or substantially equal to 20%, for example, being greater than or substantially equal to 4.0% and being less than or substantially equal to 16%. For a non-limiting example, in each sub-layer (e.g., 54-1, 54-2, 54-3), the thickness of the first layer (e.g., 120-1, 120-2, 120-3) is about 8.0 nm, and the thickness of the second layer (e.g., 122-1, 122-2, 122-3) is about 40 nm. A thickness T54 (e.g., in the direction Z, measured from an illustrated top surface of a topmost sub-layer to an illustrated bottom surface of a bottommost sub-layer) of the upper portion 54 may be less than or substantially equal to 7.0 μm, although other suitable thickness may alternatively be utilized. For a non-limiting example, the thickness T54 of the upper portion 54 may be approximately ranging from 3.0 μm to 7.0 μm. In other words, although only three sub-layers included in the upper portion 54 are shown in FIG. 16 for illustrative purposes, the number of sub-layers included in the upper portion 54 can be two, three, or more than three depending on the demand and design requirements. Owing to the multi-layer structure of the upper portion 54 (e.g., the stack of the bi-layer structures) and the multi-layer structure of the lower portion 50 (e.g., the bi-layer structure) included in the IVR 10E, the anti-ferromagnetic layer and the ferromagnetic layer being adjacent thereto undergoes the exchange coupling of magnetic dipole during the operation, which promotes anisotropy field increment and then leads to an increasement in the operation frequency of the IVR 10E (e.g., boosted to be greater than 100 MGz), thereby improving the performance of a semiconductor device equipped with the IVR 10E. In some embodiments, for the IVR 10E, a width W54 of the upper portion 54 is less than a width W50 of the lower portion 50 by a distance D. The distance D may be approximately ranging from 3.0 μm to 5.0 μm, although other suitable distance may alternatively be utilized. Owing to the configuration (e.g., the presence of the distance D), the inductance of the IVR 10E is increased, so that an overall occupied area of the IVR 10E can be reduced (if with the same value of the inductance), thereby further improving the performance of the semiconductor device equipped with the IVR 10E.

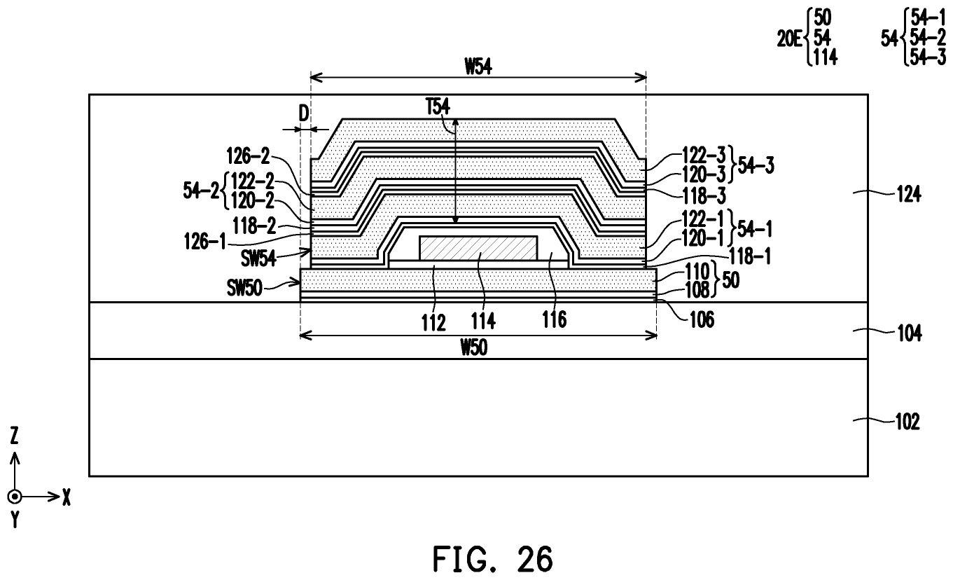

Similarly, the IVR 20E of FIG. 26 is similar to the IVR 10E of FIG. 16; the difference is that, in the IVR 20E of FIG. 26, a bottommost upper stacking unit (including the sub-layer (e.g., upper portion 54-1) and the adhesive layer 118-1) is in physical contact with (e.g., in direct contact with) the lower stacking unit (including lower portion 50 and the adhesive layer 106). In such alternative embodiments, sidewalls of the dielectric layer 112 and the dielectric layer 116 are covered by the upper stacking unit. For example, the conductive layer 114 is completely enclosed by the dielectric layer 112 and the dielectric layer 116, where the conductive layer 114 is completely enclosed by and spacing apart from the upper stacking unit and the lower stacking unit of the IVR 20E.

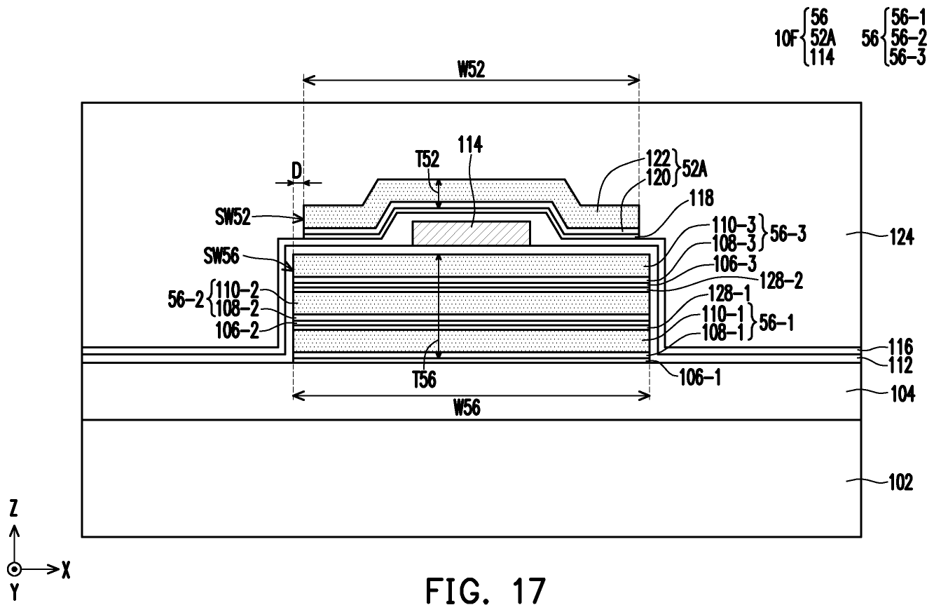

In some alternative embodiments, a IVR 10F of FIG. 17 is similar to the IVR 10A of FIG. 11 and FIG. 12; the difference is that, in the IVR 10F of FIG. 17, a lower portion 56 is adopted, instead of the lower portion 50. Referring to FIG. 17, in some embodiments, the IVR 10F includes a conductive layer 114, a lower portion 56 underlying the conductive layer 114, and an upper portion 52A overlying the conductive layer 114, where the conductive layer 114 is surrounded by and separated from the lower portion 56 and the upper portion 52A. As shown in FIG. 17, the lower portion 56 may include a plurality of sub-layers (e.g., lower portions 56-1, 56-2, and 56-3) sequentially stacked on one another, and each of the sub-layers (e.g., 56-1, 56-2, 56-3) may include a bi-layer structure having a first layer (e.g., 108-1, 108-2, 108-3) and a second layer (e.g., 110-1, 110-2, 110-3) stacked on the first layer (e.g., 108-1, 108-2, 108-3). For example, the sub-layer (e.g., 56-1) is separated from the sub-layer (e.g., 56-2) through a dielectric layer 128-1, and the sub-layer (e.g., 56-2) is separated from the sub-layer (e.g., 56-3) through a dielectric layer 128-2. Owing to the presences of the dielectric layers 128-1, 128-2, the eddy current loss can be suppressed, thereby ensuring the performance of the IVR 10F. The dielectric layers 128-1, 128-2 may be referred to as isolation layers or isolation structures.

In some embodiments, an adhesive layer 106-1 is disposed between the dielectric layer 104 and the sub-layer (e.g., 56-1), an adhesive layer 106-2 is disposed between the sub-layer (e.g., 56-1) and the sub-layer (e.g., 56-2), and an adhesive layer 106-3 is disposed between the sub-layer (e.g., 56-2) and the sub-layer (e.g., 56-3). Owing to the adhesive layers 106-1, 106-2 and 106-3, the delamination between the sub-layers (e.g., 56-1, 56-2, and 56-3) and between the dielectric layer 104 and the lower portion 56 can be suppressed, thereby ensuring the reliability of the IVR 10F. The formations and materials of the conductive layer 114 and the upper portion 52A have been discussed in FIG. 5 through FIG. 12, the formations and materials of the adhesive layers (e.g., 106-1, 106-2, 106-3), the first layers (e.g., 108-1, 108-2, 108-3) and the second layers (e.g., 110-1, 110-2, 110-3) are substantially identical to or similar to the formations and materials of the adhesive layer 106, the first layer 108 and the second layer 110 as previously described in FIG. 1 and FIG. 4, and the formations and materials of the dielectric layer (128-1, 128-2) are substantially identical to or similar to the formations and materials of the dielectric layers 104, 112, 116 and/or 124 as previously described in FIG. 1, FIG. 2 and FIG. 9 through FIG. 12; thus, are not repeated therein for brevity.

As shown in the cross-sectional view of FIG. 17, a sidewall SW56 of the lower portion 56 is constituted by sidewalls (not labeled) of the sub-layers (e.g., 56-1, 56-2, 56-3). The sidewall SW56 of the lower portion 56 is a substantially vertical sidewall, for example. However, the disclosure is not limited thereto; alternatively, the sidewall SW56 of the lower portion 56 may adopt the modifications of the upper portion 52A as previously described in FIG. 13 through FIG. 15. In some embodiments, one adhesive layer (e.g., 106-1, 106-2, 106-3, or so on) and a respective one of the sub-layers (e.g., 56-1, 56-2, 56-3, or so one) including the first layer (e.g., 108-1, 108-2, 108-3 or so on) and the second layer (e.g., 110-1, 110-2, 110-3, or so on) may together be considered as one lower stacking unit of the IVR.

In some embodiments, for each sub-layer (e.g., 56-1, 56-2, 56-3), a ratio of a thickness (e.g., T108) of the first layer 108-1, 108-2, 108-3 to a thickness (e.g., T110) of the second layer 110-1, 110-2, 110-3 is greater than or substantially equal to 4% and is less than or substantially equal to 20%, for example, being greater than or substantially equal to 4.0% and being less than or substantially equal to 16%. For a non-limiting example, in each sub-layer (e.g., 56-1, 56-2, 56-3), the thickness of the first layer (e.g., 108-1, 108-2, 108-3) is about 8.0 nm, and the thickness of the second layer (e.g., 110-1, 110-2, 110-3) is about 40 nm. A thickness T56 (e.g., in the direction Z, measured from an illustrated top surface of a topmost sub-layer to an illustrated bottom surface of a bottommost sub-layer) of the lower portion 56 may be less than or substantially equal to 7.0 μm, although other suitable thickness may alternatively be utilized. For a non-limiting example, the thickness T56 of the lower portion 56 may be approximately ranging from 3.0 μm to 7.0 μm. In other words, although only three sub-layers included in the lower portion 56 are shown in FIG. 17 for illustrative purposes, the number of sub-layers included in the lower portion 56 can be two, three, or more than three depending and the demand and design requirements. Owing to the multi-layer structure of the upper portion 52A (e.g., the bi-layer structure) and the multi-layer structure of the lower portion 56 (e.g., the stack of the bi-layer structures) included in the IVR 10F, the anti-ferromagnetic layer and the ferromagnetic layer being adjacent thereto undergoes the exchange coupling of magnetic dipole during the operation, which promotes anisotropy field increment and then leads to an increasement in the operation frequency of the IVR 10F (e.g., boosted to be greater than 100 MGz), thereby improving the performance of a semiconductor device equipped with the IVR 10F. In some embodiments, for the IVR 10F, a width W52 of the upper portion 52A is less than a width W56 of the lower portion 56 by a distance D. The distance D may be approximately ranging from 3.0 μm to 5.0 μm, although other suitable distance may alternatively be utilized. Owing to the configuration (e.g., the presence of the distance D), the inductance of the IVR 10F is increased, so that an overall occupied area of the IVR 10F can be reduced (if with the same value of the inductance), thereby further improving the performance of the semiconductor device equipped with the IVR 10F.

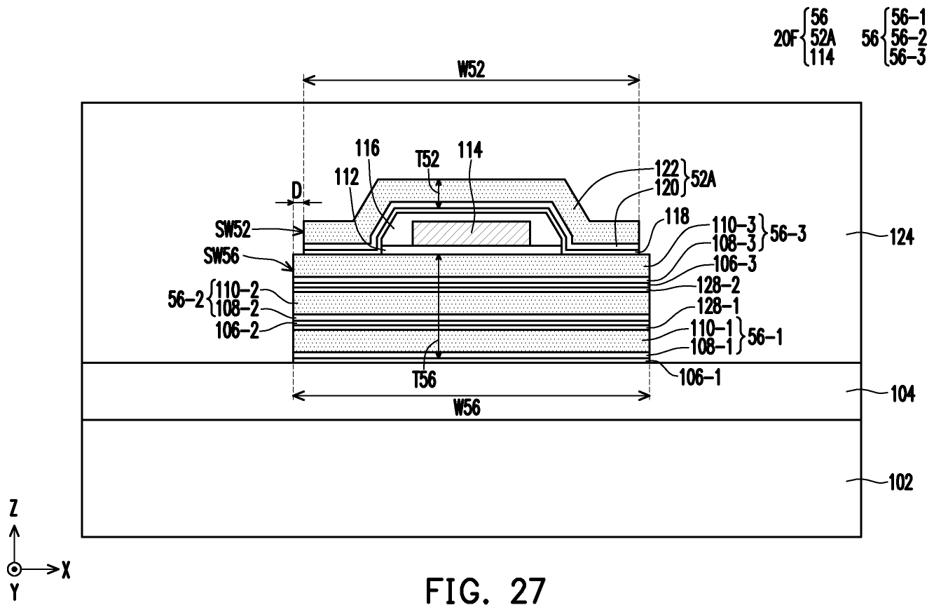

Similarly, the IVR 20F of FIG. 27 is similar to the IVR 10F of FIG. 17; the difference is that, in the IVR 20F of FIG. 27, the upper stacking unit (including the upper portion 52A and the adhesive layer 118) is in physical contact with (e.g., in direct contact with) an uppermost lower stacking unit (including the sub-layer (e.g., lower portion 56-3) and the adhesive layer 106-3). In such alternative embodiments, sidewalls of the dielectric layer 112 and the dielectric layer 116 are covered by the upper stacking unit. For example, the conductive layer 114 is completely enclosed by the dielectric layer 112 and the dielectric layer 116, where the conductive layer 114 is completely enclosed by and spacing apart from the upper stacking unit and the lower stacking unit of the IVR 20F.

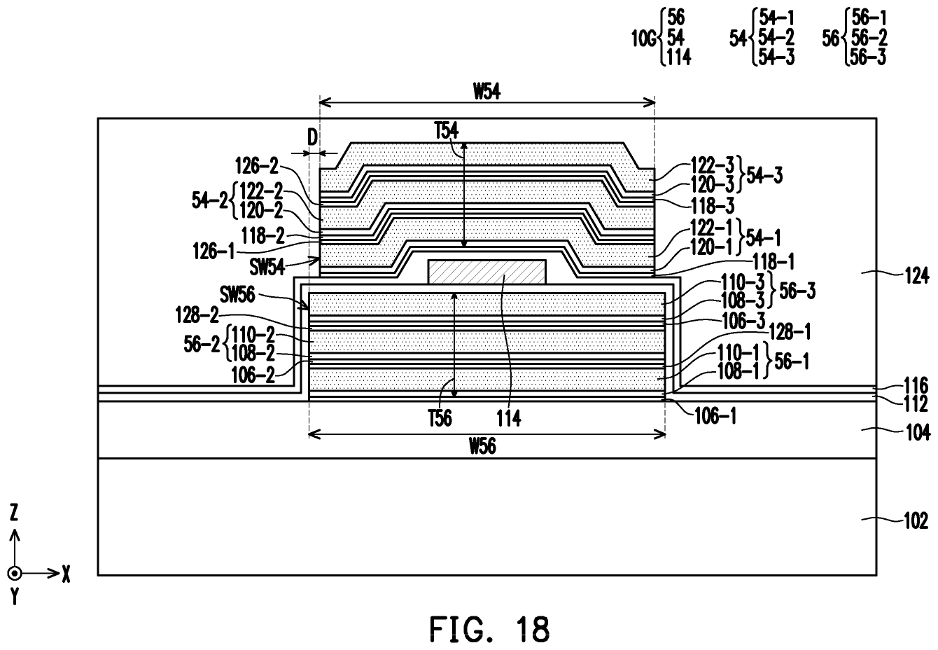

In some alternative embodiments, a IVR 10G of FIG. 18 is similar to the IVR 10A of FIG. 11 and FIG. 12; the difference is that, in the IVR 10G of FIG. 18, an upper portion 54 and a lower portion 56 are adopted, instead of the upper portion 52A and the lower portion 50. Referring to FIG. 18, in some embodiments, the IVR 10G includes a conductive layer 114, a lower portion 56 underlying the conductive layer 114, and an upper portion 54 overlying the conductive layer 114 and the lower portion 56, where the conductive layer 114 is surrounded by and separated from the lower portion 56 and the upper portion 54. The formations and materials of the conductive layer 114 has been discussed in FIG. 5 through FIG. 8, the details of the adhesive layers (e.g., 106-1, 106-2, 106-3), the first layers (e.g., 108-1, 108-2, 108-3), the second layers (e.g., 110-1, 110-2, 110-3) and the dielectric layers (e.g., 128-1, 128-2) have been discussed in FIG. 17 in conjunction with FIG. 1 through FIG. 4, the details of the adhesive layers (e.g., 118-1, 118-2, 118-3), the first layers (e.g., 120-1, 120-2, 120-3), the second layers (e.g., 122-1, 122-2, 122-3) and the dielectric layers (e.g., 126-1, 126-2) have been discussed in FIG. 16 in conjunction with FIG. 11 and FIG. 12, and thus are not repeated therein for brevity. In addition, for example, shown in the cross-sectional view of FIG. 18, a sidewall SW54 of the upper portion 54 is constituted by sidewalls (not labeled) of the sub-layers (e.g., 54-1, 54-2, 54-3), and a sidewall SW56 of the lower portion 56 is constituted by sidewalls (not labeled) of the sub-layers (e.g., 56-1, 56-2, 56-3). The sidewall SW54 of the upper portion 54 and/or the sidewall SW56 of the lower portion 56 may independently be a substantially vertical sidewall. However, the disclosure is not limited thereto; alternatively, the sidewall SW54 of the upper portion 54 and/or the sidewall SW56 of the lower portion 56 may independently adopt the modifications of the upper portion 52A as previously described in FIG. 13 through FIG. 15.

Owing to the multi-layer structure of the upper portion 54 (e.g., the upper portions 54-1, 54-2, 54-3 having the stack of the bi-layer structures) and the multi-layer structure of the lower portion 56 (e.g., the lower portion 56-1, 56-2, 56-3 having the stack of the bi-layer structures) included in the IVR 10G, the anti-ferromagnetic layer and the ferromagnetic layer being adjacent thereto undergoes the exchange coupling of magnetic dipole during the operation, which promotes anisotropy field increment and then leads to an increasement in the operation frequency of the IVR 10G (e.g., boosted to be greater than 100MGz), thereby improving the performance of a semiconductor device equipped with the IVR 10G. In some embodiments, for the IVR 10G, a width W54 of the upper portion 54 is less than a width W56 of the lower portion 56 by a distance D. The distance D may be approximately ranging from 3.0 μm to 5.0 μm, although other suitable distance may alternatively be utilized. Owing to the configuration (e.g., the presence of the distance D), the inductance of the IVR 10G is increased, so that an overall occupied area of the IVR 10G can be reduced (if with the same value of the inductance), thereby further improving the performance of the semiconductor device equipped with the IVR 10G.

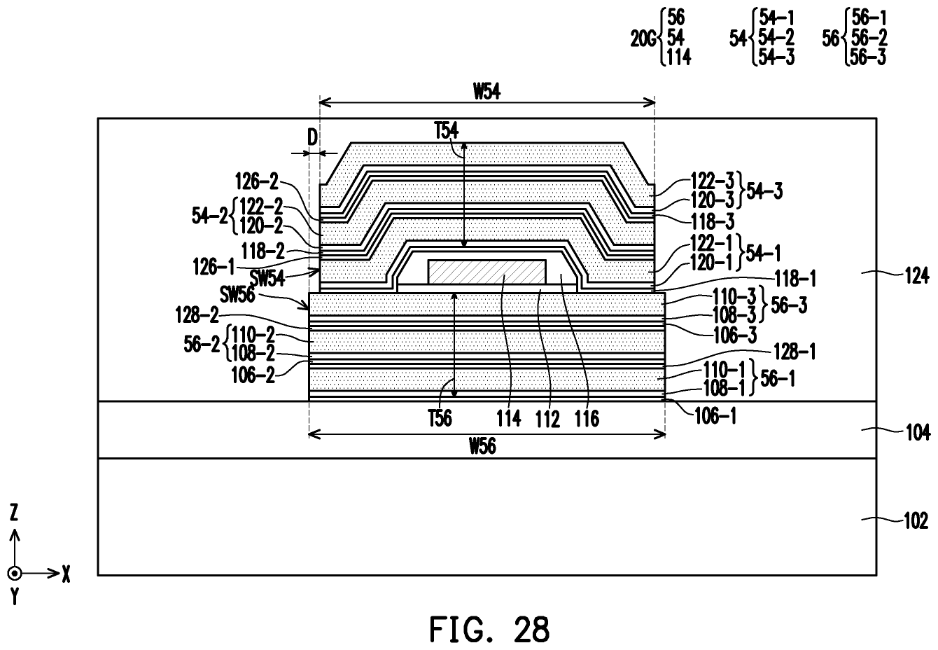

Similarly, the IVR 20G of FIG. 28 is similar to the IVR 10G of FIG. 18; the difference is that, in the IVR 20G of FIG. 28, a bottommost upper stacking unit (including the sub-layer (e.g., upper portion 54-1) and the adhesive layer 118-1) is in physical contact with (e.g., in direct contact with) an uppermost lower stacking unit (including the sub-layer (e.g., lower portion 56-3) and the adhesive layer 106-3). In such alternative embodiments, sidewalls of the dielectric layer 112 and the dielectric layer 116 are covered by the upper stacking unit. For example, the conductive layer 114 is completely enclosed by the dielectric layer 112 and the dielectric layer 116, where the conductive layer 114 is completely enclosed by and spacing apart from the upper stacking unit and the lower stacking unit of the IVR 20G.

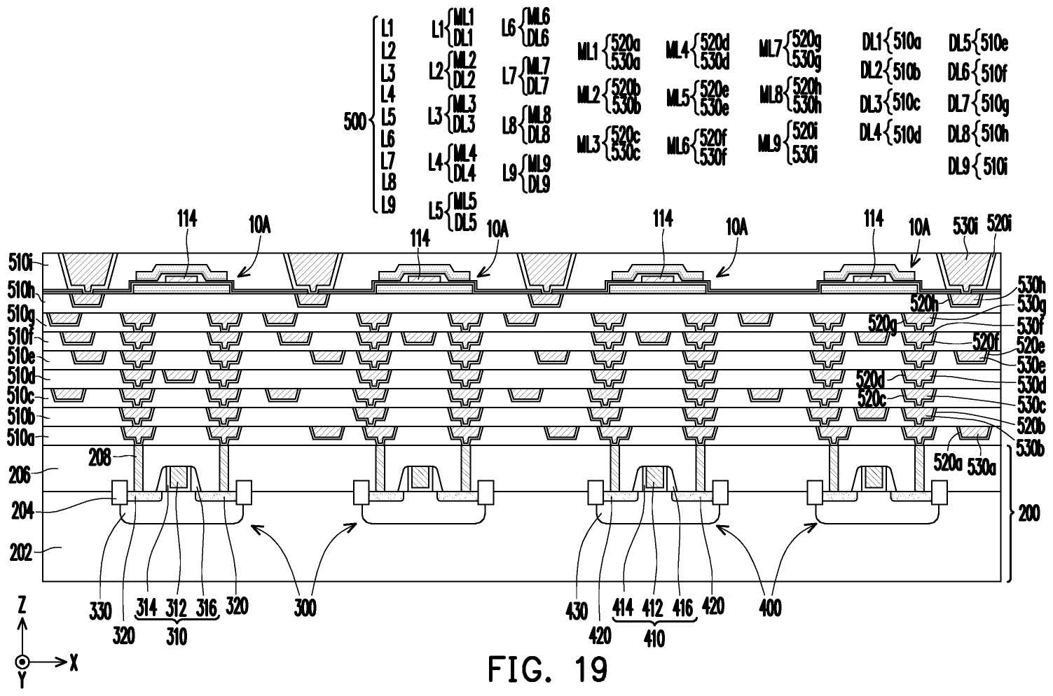

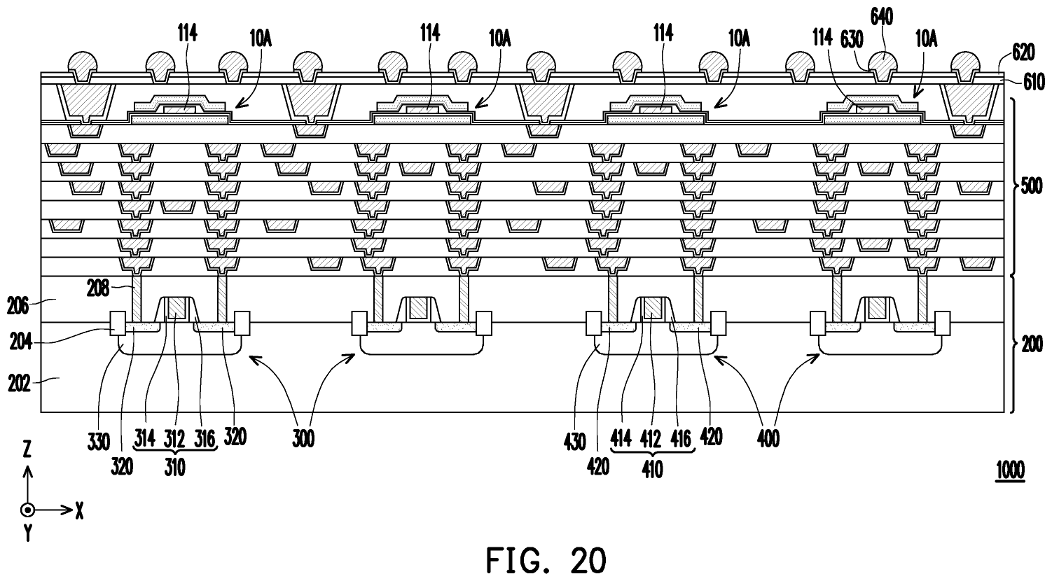

In some embodiments, the IVR (e.g., 10A, 10B, 10C, 10D, 10E, 10F, 10G, 20A, 20B, 20C, 20D, 20E, 20F, 20G and/or their modifications) of the disclosure may be adopted in a semiconductor device (e.g., a logic die, a memory die, a system-on-chip (SoC), a system-on-integrated circuit (SoIC)). FIG. 19 to FIG. 20 are schematic plane or cross-sectional views of various stages in manufacturing a semiconductor device (e.g., 1000) with an integrated voltage regulator in accordance with some embodiments of the disclosure. In some embodiments, the manufacturing method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated.

Referring to FIG. 19, in some embodiments, an initial structure is provided. For example, the initial structure includes a substrate 200 and an interconnect 500 disposed on the substrate 200, as shown in FIG. 19. For example, the substrate 200 includes including a wide variety of components (also referred to as semiconductor components) formed in a semiconductor substrate 202. The components may include active components, passive components, or a combination thereof. The components may include integrated circuits devices. The components may include transistors, capacitors, resistors, diodes, photodiodes, fuse devices, jumpers, inductors, or other similar devices. The functions of the components may include memory, processors, sensors, amplifiers, power distribution, input/output circuitry, or the like.

In some embodiments, the semiconductor substrate 202 includes a bulk semiconductor substrate, a crystalline silicon substrate, a doped semiconductor substrate (e.g., p-type semiconductor substrate or n-type semiconductor substrate), a semiconductor-on-insulator (SOI) substrate, or the like. In certain embodiments, the semiconductor substrate 202 includes one or more doped regions or various types of doped regions, depending on design requirements. In some embodiments, the doped regions are doped with p-type and/or n-type dopants. For example, the p-type dopants are boron or BF₂ and the n-type dopants are phosphorus or arsenic. The doped regions may be configured for an n-type metal-oxide-semiconductor (NMOS) transistor or a p-type MOS (PMOS) transistor. The semiconductor substrate 202 may be a wafer, such as a silicon wafer. Generally, the SOI substrate is a layer of a semiconductor material formed on an insulator layer. The insulator layer is, for example, a buried oxide (BOX) layer, a silicon oxide layer, or the like. Other substrates, such as a multi-layered or gradient substrate may also be used. In some alternative embodiments, the semiconductor substrate 202 includes a semiconductor substrate made of other suitable elemental semiconductor, such as diamond or germanium; a suitable compound semiconductor, such as gallium arsenide, silicon carbide, gallium phosphide, indium phosphide, indium arsenide and indium antimonide, an alloy semiconductor such as SiGe, GaAsP, AlInAs, AlGaAs, GalnAs, GalnP and GalnAsP or combinations thereof. For example, the semiconductor substrate 202 is a silicon bulk substrate.

As shown in FIG. 19, the components (such as one or more transistors 300 and one or more transistors 400) may be formed in the semiconductor substrate 202. In some embodiments, a plurality of isolation structures 204 are formed in the semiconductor substrate 202 for separating the transistors 300 and the transistors 400. In certain embodiments, the isolation structures 204 are trench isolation structures. In other embodiments, the isolation structures 204 includes local oxidation of silicon (LOCOS) structures. In some embodiments, the insulator material of the isolation structures 204 includes silicon oxide, silicon nitride, silicon oxynitride, a spin-on dielectric material, or a low-k dielectric material. For example, the low-k dielectric material generally has a dielectric constant lower than 3.9. In one embodiment, the insulator material may be formed by CVD (such as HDP-CVD and SACVD) or formed by spin-on. In certain embodiments, the components (such as the transistors 300 and the transistors 400) and the isolation structures 204 are formed in the substrate 200 during the front-end-of-line (FEOL) processes. In one embodiment, the transistors 300, 400 are formed following the complementary MOS (CMOS) processes. The number and configurations of the components formed in the semiconductor substrate 202 should not be limited by the embodiments or drawings of this disclosure. That is, the number of the components may be more than four. It is understood that the number and configurations of the components may have different material or configurations depending on product designs.

The transistors 300 and the transistors 400 may be a PMOS transistor. For example, each of the transistors 300 includes a gate structure 310 and source/drain regions 320 located at two opposite sides of the gate structure 310, where the gate structure 310 is formed on an n-well region 330, and the source/drain regions 320 are formed in the n-well region 330. In one embodiment, the gate structure 310 includes a gate electrode 312, a gate dielectric layer 314 and a gate spacer 316. The gate dielectric layer 314 may spread between the gate electrode 312 and the semiconductor substrate 202, and may or may not further cover a sidewall of the gate electrode 312. The gate spacer 316 may laterally surround the gate electrode 312 and the gate dielectric layer 314. In one embodiment, the source/drain regions 320 include doped regions of p-type dopant that are formed in the n-well region 330 by ion implantation. In an alternative embodiment, the source/drain regions 320 include epitaxial structures formed in and protruding from a surface of the semiconductor substrate 202 that are formed by epitaxial growth.

For example, each of the transistors 400 includes a gate structure 410 and source/drain regions 420 located at two opposite sides of the gate structure 410, where the gate structure 410 is formed on an n-well region 430, and the source/drain regions 420 are formed in the n-well region 430. In one embodiment, the gate structure 410 includes a gate electrode 412, a gate dielectric layer 414 and a gate spacer 416. The gate dielectric layer 414 may spread between the gate electrode 412 and the semiconductor substrate 202, and may or may not further cover a sidewall of the gate electrode 412. The gate spacer 416 may laterally surround the gate electrode 412 and the gate dielectric layer 414. In one embodiment, the source/drain regions 420 include doped regions of p-type dopant that are formed in the n-well region 430 by ion implantation. In an alternative embodiment, the source/drain regions 420 include epitaxial structures formed in and protruding from a surface of the semiconductor substrate 202 that are formed by epitaxial growth.

Alternatively, each of the transistors 300 and the transistors 400 may be a NMOS transistor. For example, the transistor 30 includes a gate structure 310 and source/drain regions 320 located at two opposite sides of the gate structure 310, where the gate structure 310 is formed on a p-well region 330, and the source/drain regions 320 are formed in the p-well region 330. In one embodiment, the gate structure 310 includes a gate electrode 312, a gate dielectric layer 314 and a gate spacer 316. The gate dielectric layer 314 may spread between the gate electrode 312 and the semiconductor substrate 202, and may or may not further cover a sidewall of the gate electrode 312. The gate spacer 316 may laterally surround the gate electrode 312 and the gate dielectric layer 314. In one embodiment, the source/drain regions 320 include doped regions of n-type dopant that are formed in the p-well region 330 by ion implantation. In an alternative embodiment, the source/drain regions 320 include epitaxial structures formed in and protruding from a surface of the semiconductor substrate 202 that are formed by epitaxial growth.

For example, each of the transistors 400 includes a gate structure 410 and source/drain regions 420 located at two opposite sides of the gate structure 410, where the gate structure 410 is formed on a p-well region 430, and the source/drain regions 420 are formed in the p-well region 430. In one embodiment, the gate structure 410 includes a gate electrode 412, a gate dielectric layer 414 and a gate spacer 416. The gate dielectric layer 414 may spread between the gate electrode 412 and the semiconductor substrate 202, and may or may not further cover a sidewall of the gate electrode 412. The gate spacer 416 may laterally surround the gate electrode 412 and the gate dielectric layer 414. In one embodiment, the source/drain regions 420 include doped regions of n-type dopant that are formed in the p-well region 430 by ion implantation. In an alternative embodiment, the source/drain regions 420 include epitaxial structures formed in and protruding from a surface of the semiconductor substrate 202 that are formed by epitaxial growth.

In further alternative embodiments, one of the transistors 300 and 400 may have a type being different from the types of the rest of the transistors 300 and 400. The disclosure is not limited thereto. In one non-limiting example, the transistors 300 are PMOS transistors, and the transistors 400 are NMOS transistors; or vice versa.

As illustrated in FIG. 19, for example, the substrate 200 further includes a dielectric layer 206 stacked on the semiconductor substrate 202 and a plurality of contact plugs 208 penetrating through the dielectric layer 206 to electrically connect to the transistors 300 and 400. In certain embodiments, the dielectric layer 206 and the contact plugs 208 are also formed in the structure 200 during the FEOL processes. The dielectric layer 206 may laterally surround the gate structures 310 and 410 and cover the source/drain regions 320 and 420 for providing protections to the components formed in/on the semiconductor substrate 202. Some of the contact plugs 208 may penetrate through the dielectric layer 206 in order to establish electrical connection with the source/drain regions 320 and 420, while others of the contact plugs 208 (not shown) may penetrate through the dielectric layer 206 to establish electrical connection with the gate electrodes (e.g. the gate electrodes 312, 412) of the gate structures 310 and 410, in order to provide terminals for electrical connections to later-formed components (e.g. an interconnect or interconnect structure) or external components.

The dielectric layer 206 may be referred to as an interlayer dielectric (ILD) layer, while the contact plugs 208 may be referred to as metal contacts or metallic contacts. For example, the contact plugs 208 electrically connected to the source/drain regions 320, 420 are referred to as source/drain contacts, and the contact plugs 208 electrically connected to the gate electrodes 312, 412 are referred to as gate contacts. In some embodiments, the contact plugs 208 may include copper (Cu), copper alloys, nickel (Ni), aluminum (Al), manganese (Mn), magnesium (Mg), silver (Ag), gold (Au), tungsten (W), a combination of thereof, or the like. The contact plugs 208 may be formed by, for example, plating such as electroplating or electroless plating, CVD such as PECVD, ALD, and PVD, a combination thereof, or the like.

In some embodiments, the dielectric layer 206 includes silicon oxide, silicon nitride, silicon carbide, silicon oxynitride, silicon carbonitride, silicon carbide oxynitride, spin-on glass (SOG), phosphosilicate glass (PSG), borosilicate glass (BSG), borophosphosilicate glass (BPSG), fluorinated silica glass (FSG), carbon doped silicon oxide (e.g., SiCOH), polyimide, and/or a combination thereof. In alternative embodiments, the dielectric layer 206 include low-k dielectric materials. For example, the low-k dielectric material generally has a dielectric constant lower than 3.9. Examples of low-k dielectric materials may include BLACK DIAMOND® (Applied Materials of Santa Clara, Calif.), Xerogel, Acrogel, amorphous fluorinated carbon, Parylene, BCB, Flare, SILK® (Dow Chemical, Midland, Mich.), hydrogen silsesquioxane (HSQ) or fluorinated silicon oxide (SiOF), and/or a combination thereof. It is understood that the dielectric layer 206 may include one or more dielectric materials. For example, the dielectric layer 206 include a single-layer structure or a multilayer structure. In some embodiments, the dielectric layer 206 is formed to a suitable thickness by CVD such as FCVD, HDP-CVD and SACVD, spin-on, sputtering, or other suitable methods.

A seed layer (not shown) may be optionally formed between the dielectric layer 206 and the contact plugs 208. That is, for example, the seed layer covers a bottom surface and sidewalls of each of the contact plugs 208. In some embodiments, the seed layer is a metal layer, which may be a single layer or a composite layer comprising a plurality of sub-layers formed of different materials. In some embodiments, the seed layer includes copper layer and the seed layer includes a titanium layer and a copper layer over the titanium layer. The seed layer is formed using, for example, PVD or the like. In one embodiment, the seed layer may be omitted.

In addition, an additional barrier layer or adhesive layer (not shown) may be optionally formed between the contact plugs 208 and the dielectric layer 206. Owing to the additional barrier layer or adhesive layer, it is able to prevent the seed layer and/or the contact plugs 208 from diffusing to the underlying layers and/or the surrounding layers. The additional barrier layer or adhesive layer may include Ti, TiN, Ta, TaN, a combination thereof, a multilayer thereof, or the like, and may be formed using CVD, ALD, PVD, a combination thereof, or the like. In an alternative embodiment of which the seed layer is included, the additional barrier layer or adhesive layer is interposed between the diclectric layer 206 and the seed layer, and the seed layer is interposed between the contact plugs 208 and the additional barrier layer or adhesive layer. In one embodiment, the additional barrier layer or adhesive layer may be omitted.

In some embodiments, the interconnect 500 is formed on the substrate 200. For example, as show in FIG. 19, the interconnect 500 includes a plurality of build-up layers L1, L2, L3, L4, L5, L6, L7, L8 and L9) sequentially stacked on one another along the direction Z over the substrate 200. In some embodiments, the build-up layer L1 is disposed on (e.g., in physical contact with) and electrically coupled to the components such as the transistors 300 and 400 through the contact plugs 208 for providing routing function thereto. In the case, the build-up layer L2 is disposed on (e.g., in physical contact with) and electrically connected to the build-up layer L1, and thus is electrically coupled to the components such as the transistors 300 and 400 through the contact plugs 208 and the build-up layer L1 for providing routing function thereto. The build-up layer L3 is disposed on (e.g., in physical contact with) and electrically connected to the build-up layer L2, and thus is electrically coupled to the components such as the transistors 300 and 400 through the contact plugs 208 and the build-up layers L1-L2 for providing routing function thereto. The build-up layer L4 is disposed on (e.g., in physical contact with) and electrically connected to the build-up layer L3, and thus is electrically coupled to the components such as the transistors 300 and 400 through the contact plugs 208 and the build-up layers L1-L3 for providing routing function thereto. The build-up layer L5 is disposed on (e.g., in physical contact with) and electrically connected to the build-up layer L4, and thus is electrically coupled to the components such as the transistors 300 and 400 through the contact plugs 208 and the build-up layers L1-L4 for providing routing function thereto. The build-up layer L6 is disposed on (e.g., in physical contact with) and electrically connected to the build-up layer L5, and thus is electrically coupled to the components such as the transistors 300 and 400 through the contact plugs 208 and the build-up layers L1-L5 for providing routing function thereto. The build-up layer L7 is disposed on (e.g., in physical contact with) and electrically connected to the build-up layer L6, and thus is electrically coupled to the components such as the transistors 300 and 400 through the contact plugs 208 and the build-up layers L1-L6 for providing routing function thereto. The build-up layer L8 is disposed on (e.g., in physical contact with) and electrically connected to the build-up layer L7, and thus is electrically coupled to the components such as the transistors 300 and 400 through the contact plugs 208 and the build-up layers L1-L7 for providing routing function thereto. The build-up layer L9 is disposed on (e.g., in physical contact with) and electrically connected to the build-up layer L8, and thus is electrically coupled to the components such as the transistors 300 and 400 through the contact plugs 208 and the build-up layers L1-L8 for providing routing function thereto. For example, the build-up layers L1 through L9 are electrically coupled to each other. The build-up layers L1-L9 may be referred to as a first build-up layer L1, a second build-up layer L2, a third build-up layer L3, a fourth build-up layer L4, a fifth build-up layer L9, a sixth build-up layer L6, a seventh build-up layer L7, an eighth build-up layer L8, and a ninth build-up layer L9, respectively.

The formation of the build-up layer L1 may include, but not limited to, forming a blanket layer of a dielectric material (not shown) over the substrate 200 to cover up the components such as the transistors 300 and 400; patterning the dielectric material blanket layer to form a dielectric layer 510a, where a plurality of first openings (not label) penetrate through the dielectric layer 510a; forming a seed layer 520a in the first openings; and forming a conductive material in the opening over the seed layer 520a to form a conductive layer 530a over the seed layer 520a so to form a metallization layer ML1 in the first openings formed in the dielectric layer 510a, thereby forming the build-up layer L1. For example, as shown in FIG. 19, the metallization layer ML1 of the build-up layer L1 includes the seed layer 520a and the conductive layer 530a standing thereon and electrically connected thereto, and is laterally covered by a dielectric structure DL1 of the build-up layer L1, where the dielectric structure DL1 includes the dielectric layer 510a. As shown in FIG. 19, for example, the conductive layer 530a is electrically connected to the transistors 300 and 400 through the seed layer 520a and the conductive plugs 208.

In some embodiments, the material of the dielectric layer 510a may be polyimide (PI), PBO, BCB, a nitride such as silicon nitride, an oxide such as silicon oxide, PSG, BSG, BPSG, a combination thereof, or the like, which may be patterned using a photolithography and/or etching process. The etching process may include a dry etching, a wet etching, or a combination thereof. After the etching process, a cleaning step may be optionally performed, for example to clean and remove the residue generated from the etching process. In some embodiments, the dielectric material blanket layer is formed by suitable fabrication techniques such as spin-on coating, CVD (e.g., PECVD), or the like. For example, the material of the dielectric layer 510a is silicon oxide. The first openings formed in the dielectric layer 510a each may include a trench hole and a via hole underlying and spatially communicated to the trench hole. In some embodiments, the first openings each include a dual damascene structure. The formation of the first openings is not limited to the disclosure. The formation of first openings (with the dual damascene structure) can be formed by any suitable forming process, such as a via first approach or a trench first approach.

A lateral size of the trench holes may be greater than a lateral size of the via holes. In some embodiments, a sidewall of each of the via holes is a slant sidewall. In alternative embodiments, the sidewall of each of the via holes is a vertical sidewall. In some embodiments, a sidewall of each of the trench holes is a slant sidewall. In alternative embodiments, the sidewall of each of the trench holes is a vertical sidewall. The sidewall of one via hole and the sidewall of a respective one trench hole may be collectively referred to as a sidewall of one opening formed in the dielectric layer 510a. For illustrative purposes, the number of the first openings does not limit the disclosure, and may be designated and selected based on the demand and layout design. Portions of the metallization layer ML1 formed in the trench holes may be referred to as conductive traces, conductive lines, or conductive wires horizontally extended (e.g., extending in a direction X and/or a direction Y), and portions of the metallization layer ML1 formed in the via holes may be referred to as conductive vias or conductive plugs vertically extended (e.g., extending in a direction Z).

In other embodiments, the dielectric material blanket layer includes two-layer structure, where a first dielectric layer includes a silicon carbide (SiC) layer, a silicon nitride (Si₃N₄) layer, an aluminum oxide layer, or the like, and the second dielectric layer (stacking on the first dielectric layer) includes a silicon oxide layer (e.g., a silicon-rich oxide (SRO) layer), a silicon nitride layer, a silicon oxynitride layer, a spin-on dielectric layer, or a low-k dielectric layer. It should be noted that the low-k dielectric layer is generally made of dielectric materials having a dielectric constant lower than 3.9. In some alternative embodiments, the first dielectric layer and the second dielectric layer have different etching selectivities. In the case, the first dielectric layer may be referred to as an etching stop layer (ESL) to prevent the underlying elements (e.g., the contact plugs 208 and the dielectric layer 206) from damage caused by the over-etching, while the second dielectric layer may be referred to as an inter-metallic layer (IML). In such alternative embodiments, the first dielectric layer and the second dielectric layer are patterned through a set(s) of photolithography and etching processes. The etching process may include a dry etching, a wet etching, or a combination thereof. After the etching process, a cleaning step may be optionally performed, for example to clean and remove the residue generated from the etching process. However, the disclosure is not limited thereto, and the etching process may be performed through any other suitable method. The first openings formed in the first dielectric layer and the second dielectric layer each may include a trench hole and a via hole underlying and spatially communicated to the trench hole. For example, the trench holes are formed in the second dielectric layer and extend from an illustrated top surface of the second dielectric layer to a position inside the second dielectric layer. For example, the via holes are formed in the second dielectric layer and the first dielectric layer and extend from the position inside the second dielectric layer to an illustrated bottom surface of the first dielectric layer. The position may be about ½ to about ⅓ of a thickness of the second dielectric layer; however, the disclosure is not limited thereto.

In some embodiments, the seed layer 520a and the conductive layer 530a are sequentially formed in the first openings by, but not limited to, conformally forming a blanket layer made of metal or metal alloy materials over the dielectric structure DL1 and extending into the first openings, so to line the sidewalls of the first openings; filling the conductive material in the first openings; and removing excess amount of the blanket layer made of metal or metal alloy materials and the conductive material over the illustrated top surface of the dielectric layer 510a, thereby the metallization layer ML1 including the seed layer 520a and the conductive layer 530a is manufactured. The removal may be performed by a planarizing process such as a mechanical grinding, a chemical mechanical polishing (CMP), and/or an etching process. After the planarizing process, a cleaning process may be optionally performed, for example to clean and remove the residue generated from the planarizing process. However, the disclosure is not limited thereto, and the planarizing process may be performed through any other suitable method.

In some embodiments, the seed layer 520a is referred to as a metal layer, which can be a single layer or a composite layer including a plurality of sub-layers formed of different materials. In some embodiments, the seed layer 520a includes titanium, copper, molybdenum, tungsten, titanium nitride, titanium tungsten, combinations thereof, or the like. For example, the seed layer 520a may include a titanium layer and a copper layer over the titanium layer. The seed layer500a may be formed using, for example, sputtering, PVD, or the like.

In some embodiments, a material of the conductive material includes a suitable conductive material, such as metal and/or metal alloy. For example, the conductive material can be Al, aluminum alloys, Cu, copper alloys, or combinations thereof (e.g., AlCu), the like, or combinations thereof. In some embodiments, the conductive material is formed by plating process or any other suitable method, which the plating process may include electroplating or electroless plating, or the like. In alternative embodiments, the conductive material may be formed by deposition. The disclosure is not limited thereto. In the case, an illustrated top surface of the metallization layer ML1 is substantially level with an illustrated top surface of the dielectric structure DL1. That is, the illustrated top surface of the metallization layer ML1 is substantially coplanar to the illustrated top surface of the dielectric structure DL1.

The formation, material, and configuration of components of each of the build-up layer L2 (e.g., a dielectric structure DL2 including a dielectric layer 510b and a metallization layer ML2 including a seed layer 520b and a conductive layer 530b), the build-up layer L3 (e.g., a dielectric structure DL3 including a dielectric layer 510c and a metallization layer ML3 including a seed layer 520c and a conductive layer 530c), the build-up layer L4 (e.g., a dielectric structure DL4 including a dielectric layer 510d and a metallization layer ML4 including a seed layer 520d and a conductive layer 530d), the build-up layer L5 (e.g., a dielectric structure DL5 including a dielectric layer 510e and a metallization layer ML5 including a seed layer 520e and a conductive layer 530c), the build-up layer L6 (e.g., a dielectric structure DL6 including a dielectric layer 510f and a metallization layer ML6 including a seed layer 520f and a conductive layer 530f), the build-up layer L7 (e.g., a dielectric structure DL7 including a dielectric layer 510g and a metallization layer ML7 including a seed layer 520g and a conductive layer 530g), the build-up layer L8 (e.g., a dielectric structure DL8 including a dielectric layer 510h and a metallization layer ML8 including a seed layer 520h and a conductive layer 530h), and the build-up layer L9 (e.g., a dielectric structure DL9 including a dielectric layer 510i and a metallization layer ML9 including a seed layer 520i and a conductive layer 530i) are similar to or substantially identical to the forming process, material, and configuration of the components of the build-up layer L1 as aforementioned above, and thus are not repeated herein for brevity. In addition, the build-up layers L1-L9 may be referred to as redistribution layers or routing layers of the interconnect 500 as shown in FIG. 19. In the disclosure, the build-up layer L9 may be referred to as a topmost build-up layer or topmost layer of the interconnect 500, the build-up layer L1 may be referred to as a bottommost build-up layer or bottommost layer of the interconnect 500, and the build-up layers L2-L8 may be referred to be as inner build-up layers, inner layers, stacking build-up layers or stacking layers of the interconnect 500. Although there are nine layers of the build-up layers are shown to be included in the interconnect 500, the number of the build-up layers included in the interconnect 500 may be selected and designated based on the demand and design requirements, and is not limited to the drawings of the disclosure. For example, the number of the build-up layers included in the interconnect 500 can be one, two, three or more, as long as the interconnect 500 can provide the proper routing function.

As illustrated in FIG. 19, at least one IVR is formed in the topmost build-up layer (e.g., L9) of the interconnect 500 and is electrically coupled to at least one of the components (e.g., 300 and/or 400) formed in the substrate 200 through the interconnect 500, so to supply and/or control a voltage supplied to the respective component(s). As shown in FIG. 19, the at least one IVR may include four IVRs 10A. However, the disclosure is not limited thereto, the number of the IVR may be selected and designed based on the demand and the design requirements. In some embodiments, the IVRs 10A and the components (e.g., 300, 400) are arranged in an electrical connection with a one-to-one configuration. Alternatively, the IVRs 10A and the components (e.g., 300, 400) may be arranged in an electrical connection with a one-to-multiple configuration, such as a one-to-two configuration, a one-to-three configuration, or the like. The disclosure is not limited thereto. The details of the IVR 10A have been discussed in FIG. 1 through FIG. 12, and thus are not repeated herein. Owing to the IVRs 10A, the performance of the semiconductor device 1000 is improved and the power consumption thereof can be reduced. The interconnect 500 may be referred to as an interconnection, an interconnect structure, a redistribution structure or a routing structure of the semiconductor device 1000 (in FIG. 20) for providing routing functions to the components included in the semiconductor substrate 202, which not only interconnecting the components, but also providing electronic connections between the IVRs and the components included in the semiconductor substrate 202 and between external electronic component(s) and the components included in the semiconductor substrate 202.

Referring to FIG. 20, in some embodiments, a passivation layer 610 and a post-passivation layer 620 are formed over the interconnect 500, in a sequent order along the direction Z. In some embodiments, the passivation layer 610 is disposed on (e.g., in physical contact with) the interconnect 500, and a plurality of first through openings penetrate through the passivation layer 610 to expose portions of a topmost layer of the metallization layers of the interconnect 500 for later electrical connections. Portions of an illustrated top surface (not label) of the conductive layer 530i of the metallization layer ML9 may be accessibly revealed by the first through openings formed in the passivation layer 610, as shown in FIG. 20. In a non-limiting example, the dielectric layer 510i of the dielectric structure DL9 is completely covered by the passivation layer 610, where the conductive layer 530i of the metallization layer ML9 is partially covered by the passivation layer 610, and the seed layer 520i of the metallization layer ML9 is either completely covered, partially exposed or completely exposed by the passivation layer 610. In other non-limiting example, the dielectric layer 510i of the dielectric structure DL9 is partially covered by the passivation layer 610, where the conductive layer 530i of the metallization layer ML9 is partially covered by the passivation layer 610, and the seed layer 520i of the metallization layer ML9 is either completely covered, partially exposed or completely exposed by the passivation layer 610. In some embodiments, sidewalls (not label) of the first through openings are slant sidewalls. Alternatively, the sidewalls of the first through openings may be vertical sidewalls.

In some embodiments, the post-passivation layer 620 is disposed on (e.g., in physical contact with) the passivation layer 610, and a plurality of second through openings penetrate through the post-passivation layer 620 to expose the portions of the topmost layer of the metallization layers of the interconnect 500 exposed by the passivation layer 610 for later electrical connections. The portions of the illustrated top surface of the conductive layer 530i of the metallization layer ML9 may be further accessibly revealed by the second through openings formed in the post-passivation layer 620, as shown in FIG. 20. In some embodiments, the second through openings formed in the post-passivation layer 620 are spatially communicated with the first through openings formed in the passivation layer 610, respectively. In a non-limiting example, the post-passivation layer 620 is positioned at an illustrated top surface (not label) of the passivation layer 610, where the sidewalls of the first through openings formed in the passivation layer 610 are free from the post-passivation layer 620, and a lateral size of the second through openings is greater than a lateral size of the first through openings. In other non-limiting example, the post-passivation layer 620 is positioned at the illustrated top surface of the passivation layer 610, where the sidewalls of the first through openings formed in the passivation layer 610 are lined with the post-passivation layer 620, and a lateral size of the second through openings is less than a lateral size of the first through openings. In some embodiments, sidewalls (not label) of the second through openings are slant sidewalls. Alternatively, the sidewalls of the second through openings may be vertical sidewalls.

In some embodiments, the passivation layer 610 and the post-passivation layer 620 independently may be a PBO layer, a PI layer or other suitable polymers. In some alternative embodiments, the passivation layer 610 and the post-passivation layer 620 independently may be made of inorganic materials, such as silicon oxide, silicon nitride, silicon oxynitride, or any suitable dielectric material. The material of the passivation layer 610 and the material of the post-passivation layer 620 may be the same. Alternatively, the material of the passivation layer 610 and the material of the post-passivation layer 620 may be different. For example, the passivation layer 610 is a silicon oxide layer, a silicon nitride layer, a silicon oxy-nitride layer, or a dielectric layer formed by other suitable dielectric materials, and the post-passivation layer 620 is a PI layer, a PBO layer, or a dielectric layer formed by other suitable polymers. In a non-limiting example, the materials of the passivation layers 610 and 620, independently, may be different from the materials of the dielectric layer 510a-510i of the interconnect 500, in part or all. In another non-limiting example, the materials of the passivation layers 610 and 620 may be the same as the materials of the dielectric layer 510a-510i of the interconnect 500. Due to at least one of the passivation layer 610 and the post-passivation layer 620, the semiconductor device 1000 may be protected from damages caused by physically crushes, device transportations, and moistures or hydrogen attacks for the environment, thereby improving the performance of the semiconductor device 1000. In alternative embodiments, at least one of the passivation layer 610 or the post-passivation layer 620 may be omitted.

Continued on FIG. 20, in some embodiments, a plurality of under-ball metallurgy (UBM) patterns 630 and a plurality of conductive terminals 640 are sequentially formed on the post-passivation layer 620 over the passivation layer 610. In some embodiments, the UBM patterns 630 each are disposed between a respective one of the conductive terminals 640 and the post-passivation layer 620. For example, the UBM patterns 630 are disposed on the post-passivation layer 620 and further extend into the second through openings formed in the post-passivation layer 620 and the first through openings formed in the passivation layer 610 to be in (physical) contact with the metallization layer ML9 exposed therefrom so to be electrically connected to the interconnect 500, and the conductive terminals 640 are disposed on (e.g., in physical contact with) and electrically connected to the UBM patterns 630. Due to the UBM patterns 630, the adhesion strength between the conductive terminals 640 and the post-passivation layer 620/passivation layer 610 is enhanced. In some embodiments, some of the UBM patterns 630 are physically connected to and electrically connected to the interconnect 500. In such cases, the conductive terminals 640 are electrically coupled to the interconnect 500 through some of the UBM patterns 630. For example, some of the conductive terminals 640 are electrically coupled to the components formed in the substrate 200 through some of the UBM patterns 630 and the interconnect 500.

In some embodiments, some of the UBM patterns 630 are physically connected to and electrically connected to the IVRs 10A (e.g., one of the end regions 114a or 114b). In such cases, the conductive terminals 640 are electrically coupled to the IVRs 10A through some of the UBM patterns 630. For example, the IVRs 10A are electrically coupled to some of the conductive terminals 640 through some of the UBM patterns 630 and one of the end regions 114a or 114b of the IVRs 10A, and the IVRs 10A are electrically coupled to the components formed in the substrate 200 through the interconnect 500 and other one of the end regions 114a or 114b of the IVRs 10A.

In some embodiments, the UBM patterns 630 are made of a metal layer including a single layer or a metallization layer including a composite layer with a plurality of sub-layers formed of different materials. In some embodiments, the UBM patterns 630 include copper, nickel, molybdenum, titanium, tungsten, titanium nitride, titanium tungsten, combinations thereof, or the like. The UBM patterns 630 may include a titanium layer and a copper layer over the titanium layer. The UBM patterns 630 may be formed using electroplating, sputtering, PVD, or the like. For example, the UBM patterns 630 are conformally formed on the post-passivation layer 620 by sputtering to extend on an outermost surface of the post-passivation layer 620 and further extend into the second through openings formed in the post-passivation layer 620 and the first through openings formed in the passivation layer 610, and thus are in physical contact with the portions of the topmost surface of the metallization layer ML9 of the interconnect 500 exposed by the passivation layer 610 and the post-passivation layer 620. The UBM patterns 630 are electrically isolated from one another. The number of the UBM patterns 630 may not be limited in this disclosure, and may correspond to the number of the portions of the topmost surface of the metallization layer ML9 of the interconnect 500 exposed by the passivation layer 610 (e.g., the first through openings formed therein) and the post-passivation layer 620 (e.g., the second through openings formed therein) overlying thereto.

In some embodiments, the conductive terminals 640 are physically connected to and electrically connected to the UBM patterns 630, and are electrically coupled to the interconnect 500 through the UBM patterns 630. In some embodiments, the conductive terminals 640 are disposed on the UBM patterns 630 by ball placement process or reflow process. For example, the conductive terminals 640 includes micro-bumps, metal pillars, electroless nickel-electroless palladium-immersion gold (ENEPIG) formed bumps, controlled collapse chip connection (C4) bumps (for example, which may have, but not limited to, a size of about 80 μm), a ball grid array (BGA) bumps or balls (for example, which may have, but not limited to, a size of about 400 μm), solder balls, or the like. The disclosure is not limited thereto. The numbers of the conductive terminals 640 is not limited to the drawings of the embodiments, and may be selected and designated based on the demand and design requirements. The number of the conductive terminals 640 may be controlled by adjusting the number of the UBM patterns 630. When solder is used, the solder may include either eutectic solder or non-eutectic solder. The solder may include lead or be lead-free, and may include Sn—Ag, Sn—Cu, Sn—Ag—Cu, or the like. The conductive terminals 640 may be solder free. The conductive terminals 640 may be referred to as conductors, conductive connectors, or conductive input/output terminals of the semiconductor device 1000 for electrical connection with external components or elements (e.g., an additional semiconductor package/device, a circuit substrate, an interposer, a surface mounted device or integrated passive device such as a capacitor, a power source, or the like, etc.).

However, the disclosure is not limited thereto. In some alternative embodiments, the UBM patterns 630 may be omitted. In such alternative embodiments, the conductive terminals 640 may be directly connected to (e.g., in physical contact with) and electrically coupled to the interconnect 500. In further alternative embodiments, the conductive terminals 640 may be omitted, as well.

In some embodiments, a dicing (or singulation) process is sequentially performed to cut through the post-passivation layer 620, the passivation layer 610, the interconnect 500 and the substrate 200 into individual and separated semiconductor devices 1000. Only one semiconductor device 1000 is shown in FIG. 20 for illustrative purposes and simplicity. In one embodiment, the singulation process is a wafer dicing process including mechanical blade sawing or laser cutting. The disclosure is not limited thereto. Up to here, the semiconductor device 1000 is manufactured. In some embodiments, the upper portions and the lower portions of the IVRs 10A are electrically isolated to (e.g., electrically floating to) the metallization layers of the interconnect 500 and the conductive elements 640. However, the disclosure is not limited thereto; alternatively, the IVRs 10A may be substituted by the IVRs 10B, 10C, 10D, 10E, 10F, 10G, 20A, 20B, 20C, 20D, 20E, 20F, 20G and their modifications, partially or entirely, where the upper portions and the lower portions of the IVRs are electrically isolated to the interconnect 500.

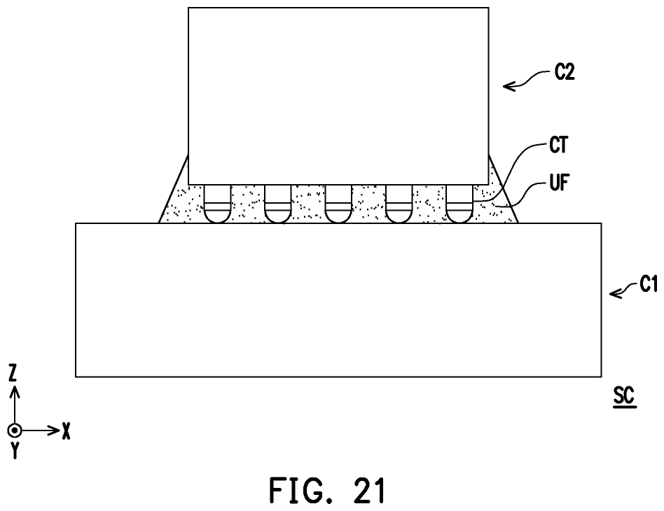

The semiconductor device 1000 and the modifications thereof may be further mounted onto another external electronical component, for example, mounted onto a circuit structure, such as a mother board, a package substrate, a printed circuit board (PCB), a printed wiring board, and/or other carrier that is capable of carrying integrated circuits. For a non-limiting example, semiconductor device 1000 and the modifications thereof may be or may be part of an integrated Fan-Out (InFO) package, an InFO package having a Package-on-Package (POP) structure, a chip-on-wafer-on-substrate (CoWoS) package, a flip chip package of an InFO package, or the like. The disclosure is not limited thereto. FIG. 21 is a schematic cross-sectional view showing an application of a semiconductor structure in accordance with some embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 21, in some embodiments, a component assembly SC including a first component C1 and a second component C2 disposed over the first component C1 is provided. The first component C1 may be or may include a circuit structure, such as a mother board, a package substrate, another PCB, a printed wiring board, an interposer, and/or other carrier that is capable of carrying integrated circuits. In some embodiments, the second component C2 mounted on the first component C1 is similar to one of the semiconductor device 1000 and the modifications thereof. In a non-limiting example, one or more semiconductor device (e.g., one or multiple semiconductor devices 1000 and/or one or multiple of the modifications of the semiconductor device 1000 may be electrically coupled to the first component C1 through a plurality of terminals CT. The terminals CT may be the conductive elements 640 as described in FIG. 20.

In some embodiments, an underfill UF is formed between the gap of the first component C1 and the second component C2 to at least laterally cover the terminals CT. Alternatively, the underfill UF is omitted. The underfill UF may be any acceptable material, such as a polymer, epoxy resin, molding underfill, or the like, for example. In one embodiment, the underfill may be formed by underfill dispensing, a capillary flow process, or any other suitable method. Owing to the underfill UF, a bonding strength between the first component C1 and the second component C2 is enhanced.

In accordance with some embodiments, an integrated voltage regulator includes a lower portion, an upper portion, and a conductive feature. The lower portion includes at least one first anti-ferromagnetic layer and at least one first ferromagnetic layer stacked on the at least one first anti-ferromagnetic layer. The upper portion includes at least one second anti-ferromagnetic layer and at least one second ferromagnetic layer stacked on the at least one second anti-ferromagnetic layer. The conductive feature interposes between the lower portion and the upper portion.

In accordance with some embodiments, a semiconductor device includes a substrate, an interconnect, and an integrated voltage regulator. The substrate includes a component. The interconnect is disposed on the substrate and electrically coupled to the component. The integrated voltage regulator is embedded in and electrically coupled to the interconnect, and includes a first portion, a second portion and a conductive layer. The first portion includes at least one first stack comprising a first anti-ferromagnetic layer and a first ferromagnetic layer stacked on the first anti-ferromagnetic layer. The second portion includes at least one second stack comprising a second anti-ferromagnetic layer and a second ferromagnetic layer stacked on the second anti-ferromagnetic layer. The conductive layer interposes between the first portion and the second portion. The conductive layer of the integrated voltage regulator is electrically coupled to the component through the interconnect.

In accordance with some embodiments, a method of manufacturing an integrated voltage regulator includes the following steps: providing a base layer; forming a first anti-ferromagnetic material over the base layer; forming a first ferromagnetic material over the first anti-ferromagnetic material; patterning the first anti-ferromagnetic material and the first ferromagnetic material to form a first stack of a first anti-ferromagnetic layer and a first ferromagnetic layer; disposing a first dielectric layer over the first stack; disposing a conductive layer over the first dielectric layer and the first stack; disposing a second dielectric layer over the conductive layer; forming a second anti-ferromagnetic material over the second dielectric layer and the conductive layer; forming a second ferromagnetic material over the second anti-ferromagnetic material; and patterning the second anti-ferromagnetic material and the second ferromagnetic material to form a second stack of a second anti-ferromagnetic layer and a second ferromagnetic layer.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. An integrated voltage regulator, comprising:
a lower portion, comprising at least one first anti-ferromagnetic layer and at least one first ferromagnetic layer stacked on the at least one first anti-ferromagnetic layer;
an upper portion, comprising at least one second anti-ferromagnetic layer and at least one second ferromagnetic layer stacked on the at least one second anti-ferromagnetic layer; and
a conductive feature, interposing between the lower portion and the upper portion.

2. The integrated voltage regulator of claim 1, wherein in a cross-section of the integrated voltage regulator in a stacking direction of the lower portion, a lateral size of the upper portion is less than a lateral size of the lower portion.

3. The integrated voltage regulator of claim 1, wherein in a cross-section of the integrated voltage regulator in a stacking direction of the lower portion, the conductive feature is placed in a space confined by the lower portion and the upper portion.

4. The integrated voltage regulator of claim 1, wherein the conductive feature is separated apart from and electrically isolating to the lower portion and the upper portion by a dielectric material.

5. The integrated voltage regulator of claim 1, wherein:
the at least one first anti-ferromagnetic layer comprises a plurality of first anti-ferromagnetic layers,
the at least one first ferromagnetic layer comprises a plurality of first ferromagnetic layers,
wherein the plurality of first anti-ferromagnetic layers and the plurality of first ferromagnetic layers are arranged in an alternated manner.

6. The integrated voltage regulator of claim 1, wherein:
the at least one second anti-ferromagnetic layer comprises a plurality of second anti-ferromagnetic layers,
the at least one second ferromagnetic layer comprises a plurality of second ferromagnetic layers,
wherein the plurality of second anti-ferromagnetic layers and the plurality of second ferromagnetic layers are arranged in an alternated manner.

7. The integrated voltage regulator of claim 1,
wherein the at least one first anti-ferromagnetic layer comprises a plurality of first anti-ferromagnetic layers, the at least one first ferromagnetic layer comprises a plurality of first ferromagnetic layers, wherein the plurality of first anti-ferromagnetic layers and the plurality of first ferromagnetic layers are arranged in an alternated manner, and
wherein the at least one second anti-ferromagnetic layer comprises a plurality of second anti-ferromagnetic layers, the at least one second ferromagnetic layer comprises a plurality of second ferromagnetic layers, wherein the plurality of second anti-ferromagnetic layers and the plurality of second ferromagnetic layers are arranged in an alternated manner.

8. The integrated voltage regulator of claim 1, wherein in a cross-section of the integrated voltage regulator in a stacking direction of the lower portion, at least one of a sidewall of the upper portion and a sidewall of the lower portion comprises a substantially vertical sidewall.

9. The integrated voltage regulator of claim 1, wherein in a cross-section of the integrated voltage regulator in a stacking direction of the lower portion, at least one of a sidewall of the upper portion and a sidewall of the lower portion comprises a slant sidewall.

10. The integrated voltage regulator of claim 1, wherein in a cross-section of the integrated voltage regulator in a stacking direction of the lower portion, at least one of a sidewall of the upper portion and a sidewall of the lower portion comprises a sidewall in form of step-shape.

11. A semiconductor device, comprising:
a substrate, comprising a component;
an interconnect, disposed on the substrate and electrically coupled to the component; and
an integrated voltage regulator, embedded in and electrically coupled to the interconnect, and comprising:
a first portion, comprising at least one first stack comprising a first anti-ferromagnetic layer and a first ferromagnetic layer stacked on the first anti-ferromagnetic layer;
a second portion, comprising at least one second stack comprising a second anti-ferromagnetic layer and a second ferromagnetic layer stacked on the second anti-ferromagnetic layer; and
a conductive layer, interposing between the first portion and the second portion,
wherein the conductive layer of the integrated voltage regulator is electrically coupled to the component through the interconnect.

12. The semiconductor device of claim 11, wherein the first portion and the second portion of the integrated voltage regulator is electrically isolated to the interconnect.

13. The semiconductor device of claim 11, wherein the least one first stack comprises a plurality of first stacks, and two immediately adjacent first stacks of the plurality of first stacks are separated from one another by an isolation structure.

14. The semiconductor device of claim 11, wherein the least one second stack comprises a plurality of second stacks, and two immediately adjacent second stacks of the plurality of second stacks are separated from one another by an isolation structure.

15. The semiconductor device of claim 11,
wherein the least one first stack comprises a plurality of first stacks, and two immediately adjacent first stacks of the plurality of first stacks are separated from one another by a first isolation structure, and
wherein the least one second stack comprises a plurality of second stacks, and two immediately adjacent second stacks of the plurality of second stacks are separated from one another by a second isolation structure.

16. The semiconductor device of claim 11, wherein in a cross-section of the semiconductor device along a stacking direction of the substrate and the interconnect, a lateral size of the first portion is less than a lateral size of the second portion.

17. A method of manufacturing an integrated voltage regulator, comprising:
providing a base layer;
forming a first anti-ferromagnetic material over the base layer;
forming a first ferromagnetic material over the first anti-ferromagnetic material;
patterning the first anti-ferromagnetic material and the first ferromagnetic material to form a first stack of a first anti-ferromagnetic layer and a first ferromagnetic layer;
disposing a first dielectric layer over the first stack;
disposing a conductive layer over the first dielectric layer and the first stack;
disposing a second dielectric layer over the conductive layer;
forming a second anti-ferromagnetic material over the second dielectric layer and the conductive layer;
forming a second ferromagnetic material over the second anti-ferromagnetic material; and
patterning the second anti-ferromagnetic material and the second ferromagnetic material to form a second stack of a second anti-ferromagnetic layer and a second ferromagnetic layer.

18. The method of claim 17, prior to forming the first anti-ferromagnetic material over the base layer, further comprising:
disposing a first adhesive material over the base layer, wherein the first anti-ferromagnetic material is formed on the first adhesive material and over the base layer, and wherein patterning the first anti-ferromagnetic material and the first ferromagnetic material to form the first stack of the first anti-ferromagnetic layer and the first ferromagnetic layer further comprises patterning the first adhesive material to form a first adhesive layer.

19. The method of claim 17, prior to forming the second anti-ferromagnetic material over the second dielectric layer and the conductive layer, further comprising:
disposing a second adhesive material over the second dielectric layer, wherein the second anti-ferromagnetic material is formed on the second adhesive material and over the second dielectric layer, and wherein patterning the second anti-ferromagnetic material and the second ferromagnetic material to form the second stack of the second anti-ferromagnetic layer and the second ferromagnetic layer further comprises patterning the second adhesive material to form a second adhesive layer.

20. The method of claim 17, wherein in a cross-section of the integrated voltage regulator, the second stack is formed to have a lateral size less than a lateral size of the first stack.
